(19) United States
(12) Patent Application Publication
(10) Pub. No.: US 2016/0280918 A1
(43) Pub. Date: Sep. 29, 2016

(54) ADDITION-CURABLE SILICONE COMPOSITION

(71) Applicant: MOMENTIVE PERFORMANCE MATERIALS JAPAN LLC, Tokyo, (JP)

(72) Inventors: Prakash KUMAR, Tokyo (JP); Hideo TAKAHASHI, Tokyo (JP)

(73) Assignee: MOMENTIVE PERFORMANCE MATERIALS JAPAN LLC, Tokyo, (JP)

(21) Appl. No.: 15/175,833

(22) Filed: Jun. 7, 2016

Related U.S. Application Data
(63) Continuation of application No. PCT/JP2014/081870, filed on Dec. 2, 2014.

(30) Foreign Application Priority Data
Dec. 16, 2013 (JP) 2013-259435
Sep. 16, 2014 (JP) 2014-187649

(51) Int. Cl. C08L 83/04; H01L 33/56; H01L 23/00; C09J 183/04

(52) U.S. Cl. CPC C08L 83/04; C09J 183/04; H01L 33/56; H01L 24/29; C08L 2203/206; C08L 2205/025; C08L 2205/05; H01L 23/296

(57) ABSTRACT

There is provide an addition-curable silicone composition from which a silicone cured product having excellent adhesiveness and external appearance, being able to protect metal, in particular, silver, from corrosion, and having less shrinkage and change in hardness due to heat, is obtained. The addition-curable silicone composition contains: 100 parts by mass of a polyorganosiloxane having alkenyl groups; an amount of a polyorganohydrogensiloxane such that an amount of Si—H groups is 0.9 to 3.0 mol relative to 1 mol of the alkenyl groups; a catalyst amount of a hydrosilylation reaction catalyst; 0.01 to 10 parts of an adhesiveness imparting agent; and 0.001 to 0.015 parts by mass, in terms of metal atoms of (R³COO)ₖM (where M is Ce, Fe, Cr, La, Nd, Pr or Sm, k is 2, 3 or 4, and R³ represents a substituted or unsubstituted hydrocarbon group having 4 to 17 carbon atoms).

### CROSS-REFERENCE TO RELATED APPLICATIONS

This application is a continuation of prior International Application No. PCT/JP2014/081870 filed on Dec. 2, 2014 which is based upon and claims the benefit of priority from Japanese Patent Applications No. 2013-259435 filed on Dec. 16, 2013 and No. 2014-187649 filed on Sep. 16, 2014; the entire contents of all of which are incorporated herein by reference.

### FIELD

The present invention relates to an addition-curable silicone composition and, in particular, to an addition-curable silicone composition from which a cured product having excellent adhesiveness and external appearance, being able to protect metal, in particular, silver, from corrosion, and having less shrinkage and change in hardness due to heat, is obtained.

### BACKGROUND

A silicone (polyorganosiloxane) composition such as silicone rubber or silicone gel forms a cured product excellent in various properties such as weather resistance, heat resistance, hardness, elongation and so on, and therefore is used for various uses.

For example, in an optical semiconductor device including a light emitting element such as a light emitting diode (LED), a silicone composition excellent in heat resistance and ultraviolet resistance property is used as a material for sealing the light emitting element. In particular, an addition-curable silicone composition which is cured utilizing hydrosilylation is cured in a short time by heating and does not generate a by-product during curing, and is therefore widely used.

Further, the addition-curable silicone composition is lower in adhesiveness than an epoxy resin and therefore, for example, Patent Reference 1 (JP-A 2010-065161) suggests that an isocyanuric derivative having an alkoxysilyl group and/or an epoxy group and having a crosslinking vinyl group and/or a hydrosilyl group is compounded in the above composition for the purpose of improving adhesiveness.

However, when the adhesiveness improving component was compounded in the addition-curable silicone composition, cracks sometimes occurred during heating due to the component and peeling from an adhered article accompanying the cracks occurred in the cured product to be obtained therefrom. These were thought to synergistically occur by simultaneous progression of shrinkage and change in hardness of the cured product due to heat. Therefore, it is desired to develop an addition-curable silicone composition with suppressed shrinkage and change in hardness due to heat of the cured product because of an adhesiveness improving component while the improvement in adhesiveness is sufficiently secured by containing the component.

On the other hand, a technique of compounding a rare-earth salt of a carboxylic acid in an addition-curable silicone composition not containing the adhesiveness improving component as described above, for the purpose of suppressing the change in hardness due to heat, is suggested (refer to Patent Reference 2(International Publication No. 2013/084699)). However, there have been no known trial of compounding a rare-earth salt of a carboxylic acid together with an adhesiveness improving component in an addition-curable silicone composition to thereby suppress the heat shrinkage of the addition-curable silicone composition cured product due to the adhesiveness improving component.

Further, the silicone composition is generally excellent in gas permeability and is thus likely to be affected by an external environment. The problem of the above optical semiconductor device or the like is that if it is exposed to a sulfur compound in atmosphere or to exhaust gas, the sulfur compound or the like permeates the cured product of the silicone composition and corrodes a metal electrode on the substrate sealed with the cured product, in particular, an Ag electrode over time to tarnish it.

### DISCLOSURE OF THE INVENTION

The present invention has been made to solve such problems, and its object is to provide an addition-curable silicone composition from which a silicone cured product having excellent adhesiveness and external appearance, being able to protect metal, in particular, silver, from corrosion, and having less shrinkage and change in hardness due to heat, is obtained.

An addition-curable silicone composition of the present invention contains:

(A) 100 parts by mass of a polyorganosiloxane having at least one alkenyl group bonded to a silicon atom in one molecule, and having neither an epoxy group nor an alkoxy group;

(B) an amount of a polyorganohydrogensiloxane having at least two hydrogen atoms bonded to silicon atoms in one molecule such that an amount of the hydrogen atoms bonded to silicon atoms is 0.9 to 3.0 mol relative to 1 mol of a total amount of the alkenyl groups contained in the (A) component;

(C) a catalyst amount of a hydrosilylation reaction catalyst;

(D) as an adhesiveness imparting agent, 0.01 to 10 parts by mass of at least one selected from (D1) an isocyanuric acid derivative having at least one selected from an epoxy group and an alkoxysilyl group and at least one selected from a hydrosilyl group and a crosslinking vinyl group and (D2) a silane or siloxane compound having at least one selected from an epoxy group and an alkoxy group, and having no isocyanuric ring; and

(E) 0.001 to 0.015 parts by mass, in terms of metal atoms, of a carboxylic acid metal salt represented by a following general formula (3),

(R³COO)ₖM (3)

where M represents a metal atom selected among Ce, Fe, Cr, La, Nd, Pr and Sm, k represents a positive number from 2 to 4, and R³ represents a substituted or unsubstituted hydrocarbon group having 4 to 17 carbon atoms.

According to the present invention, it is possible to provide an addition-curable silicone composition which is used to obtain a silicone cured product having excellent adhesiveness and external appearance, being able to protect metal, in particular, silver, from corrosion and suppress heat shrinkage and change in hardness due to heat.

### DETAILED DESCRIPTION

Hereinafter, an embodiment of the present invention will be described.

An addition-curable silicone composition of the present invention contains the following (A) to (E) components at the following respective ratios.

(A) 100 parts by mass of a polyorganosiloxane having at least one alkenyl group bonded to a silicon atom in one molecule, and having neither an epoxy group nor an alkoxy group;

(B) an amount of a polyorganohydrogensiloxane having at least two hydrogen atoms bonded to silicon atoms in one molecule such that an amount of the hydrogen atoms bonded to silicon atoms is 0.9 to 3.0 mol relative to 1 mol of a total amount of the alkenyl groups contained in the (A) component;

(C) a catalyst amount of a hydrosilylation reaction catalyst;

(D) as an adhesiveness imparting agent, 0.01 to 10 parts by mass of at least one selected from (D1) an isocyanuric acid derivative having at least one selected from an epoxy group and an alkoxysilyl group and at least one selected from a hydrosilyl group and a crosslinking vinyl group and (D2) a silane or siloxane compound having at least one selected from an epoxy group and an alkoxy group, and having no isocyanuric ring; and

(E) 0.001 to 0.015 parts by mass, in terms of metal atoms, of a carboxylic acid metal salt represented by a following general formula (3),

(R³COO)ₖM (3)

where M represents a metal atom selected among Ce, Fe, Cr, La, Nd, Pr and Sm, k represents a positive number from 2 to 4, and R³ represents a substituted or unsubstituted hydrocarbon group having 4 to 17 carbon atoms.

Hereinafter, the components will be described.

[(A) Component]

The (A) component is the polyorganosiloxane containing alkenyl groups being a base polymer of the composition of the present invention, together with the (B) component described next.

The (A) component is not particularly limited as long as it is a polyorganosiloxane having at least one alkenyl group bonded to a silicon atom in one molecule and having neither an epoxy group nor an alkoxy group.

The molecular structure of the (A) component is not particularly limited, and may be linear, branched or cyclic, and further may be a resin structure, in other words, a three-dimensional network structure. The (A) component may be composed of one kind of them or may be composed of a mixture of two or more kinds of them. In the case where the (A) component is a mixture, the number of the alkenyl groups bonded to silicon atoms in one molecule only needs to be one or more as an average of the whole (A) component. The number of the alkenyl groups is preferably 2 or more as an average of the whole (A) component. In particular, in the case of the linear (A) component, the number of the alkenyl groups is preferably 2 or more.

As the (A) component, a combination of a linear polyorganosiloxane and a polyorganosiloxane having the resin structure each of which has at least one alkenyl group bonded to a silicon atom in one molecule is preferable. Note that in this description, the term of the “linear polyorganosiloxane” includes a polyorganosiloxane in which few branches exist in a siloxane skeletal structure.

Though depending on a use, when the base polymer is composed of only the linear polyorganosiloxane, its hardness is not sufficient in some cases. In the use required to have sufficient hardness, it is particularly preferable to use the linear polyorganosiloxane and the polyorganosiloxane having the resin structure in combination. Besides, depending on the kind of an organic group contained in the polyorganosiloxane, sufficient hardness is sometimes obtained by using only the polyorganosiloxane having the resin structure.

Note that the hardness can be adjusted to some degree by using only the linear polyorganosiloxane as the (A) component and combining a later-described (F) silica powder therewith. Besides, the (F) silica powder may be used in the case where the (A) component mainly contains the linear polyorganosiloxane. That the (A) component mainly contains the linear polyorganosiloxane means the case that the content of the linear polyorganosiloxane exceeds 50 mass % relative to the total amount of the (A) component.

As the linear polyorganosiloxane in the (A) component, for example, a polyorganosiloxane (A1) represented by the following general formula (1) can be exemplified. Note (R¹₂SiO_{2/2})ₙ and (R¹₂SiO)ₙ mean same polymerization unit.

(R¹₃SiO_{1/2})(R¹₂SiO_{2/2})ₙ(R¹₃SiO_{1/2}) (1)

Note that, in the formula (1), each R¹ independently represents an alkenyl group or a monovalent unsubstituted or substituted hydrocarbon group containing none of an aliphatic unsaturated group, an epoxy group, and an alkoxy group, at least two R¹s are alkenyl groups, and an average degree of polymerization expressed by n+2 is 50 to 2,500.

Besides, as the polyorganosiloxane having the resin structure, for example, a polyorganosiloxane (A2) represented by the following average unit formula (2) can be exemplified.

(R²₃SiO_{1/2})ₐ(R²₂SiO_{2/2})_{b}(R²SiO_{3/2})_{c}(SiO_{4/2})_{d} (2)

Note that, in the formula (2), each R² independently represents an alkenyl group or a monovalent unsubstituted or substituted hydrocarbon group containing none of an aliphatic unsaturated group, an epoxy group, and an alkoxy group, at least one R² is an alkenyl group, and a is a positive number and b, c, and d are 0 or positive numbers. And, at least one of c and d is a positive number.

(Polyorganosiloxane (A1))

The siloxane skeletal structure of the polyorganosiloxane (A1) represented by the above general formula (1) can synthesize, with good control, a polymer having a high degree of polymerization as illustrated below and is therefore linear. However, few branches, for example, a plurality of branches may exist in a molecule.

The average degree of polymerization of the polyorganosiloxane (A1), namely, the number of siloxane units is expressed by n+2 made by adding 2 being the number of end groups to n in the general formula (1), and is in a range of 50 to 2,500. The average degree of polymerization is preferably 100 to 1,500. When the average degree of polymerization of the polyorganosiloxane (A1) is within the above-described range, there is no problem in synthesis (polymerization), and workability thereof is also good.

The viscosity (25° C.) of the polyorganosiloxane (A 1) is preferably 100 to 150,000 mPa·s, and particularly preferably within a range of 200 to 20,000 mPa·s. When the viscosity of the polyorganosiloxane (A1) is within this range, workability of a composition to be obtained is good, and physical properties of a silicone cured product to be obtained from this composition are also good.

Note that in this description, the viscosity refers to a viscosity measured at 25° C. by a rotational viscometer unless otherwise stated. Besides, conditions such as the number of rotations at the time of measurement are appropriately adjusted in accordance with the viscosity of an analyte and a measuring device in use.

The polyorganosiloxane (A1) has two or more alkenyl groups in one molecule. Further, the number of the alkenyl groups is preferably 250 or less, and more preferably 50 or less. When the number of the alkenyl groups is more than 250 per molecule, its cured product may become fragile and not provide sufficient strength. Note that the number of the alkenyl groups referred to here is an average number per molecule in the polyorganosiloxane (A1).

Each R¹ in the above general formula (1) independently represents an alkenyl group or a monovalent unsubstituted or substituted hydrocarbon group containing none of an aliphatic unsaturated group, an epoxy group, and an alkoxy group. In the general formula (1), the number (ratio) of R¹s in the formula (1) which are alkenyl groups is appropriately adjusted so that the number of the alkenyl groups per molecule falls within the above-described range.

When the R¹ is the monovalent unsubstituted or substituted hydrocarbon group containing none of an aliphatic unsaturated group, an epoxy group, and an alkoxy group, concrete examples of the R¹ include: alkyl groups such as a methyl group, an ethyl group, a propyl group, a butyl group, a pentyl group, and a hexyl group; aryl groups such as a phenyl group, a tolyl group, and a xylyl group; aralkyl groups such as a benzyl group and a phenethyl group; and substituted-hydrocarbon groups such as a chloromethyl group, a 3-chloropropyl group, a 3,3,3-trifluoropropyl group, a 3-cyanopropyl group, and a 3-methoxypropyl group.

When the R¹ is the alkenyl group, concrete examples of the R¹ include a vinyl group, an allyl group, a 3-butenyl group, a 4-pentenyl group, a 5-hexenyl group and the like. Because synthesis and handling of the polyorganosiloxane (A1) is easy and an addition reaction is easily carried out, the alkenyl group is preferably a vinyl group. The alkenyl group may be bonded to any silicon atom in a molecule, and part of the alkenyl groups are preferably bonded to a silicon atom at a molecule end because of excellent reactivity to be exhibited. In the polyorganosiloxane (A1), a plurality of the alkenyl groups may be the same or different, and are preferably the same in point of easy synthesis.

The polyorganosiloxane (A1) has, as R¹s other than the alkenyl groups, a plurality (the number obtained by subtracting the number of the above alkenyl groups from the number of all R¹s) of R¹s (hereinafter, the R¹ other than the alkenyl group is expressed by “R¹¹”) each representing a monovalent unsubstituted or substituted hydrocarbon group (however, containing none of an aliphatic unsaturated group, an epoxy group, and an alkoxy group). In the polyorganosiloxane (A1), the plurality of R¹¹s may be the same or different. In the point that the synthesis is easy, these R¹¹s are preferably the same. However, according to the physical properties required of a silicone cured product to be obtained, different groups may be introduced in a part of them.

Because synthesis and handling of the polyorganosiloxane (A1) is easy and excellent heat resistance can be obtained, 50% or more of the R¹¹s contained in the polyorganosiloxane (A1) are preferably methyl groups, and all of the R¹¹s are particularly preferably methyl groups.

Further, for the purpose of adjusting the hardness and elastic modulus of the silicone cured product to be obtained, a combination, in which part of the R¹¹s contained in the polyorganosiloxane (A1) are phenyl groups and all of the remaining R¹¹s are methyl groups, can be used. In this case, a combination, in which R¹s in a unit surrounded by n in the formula (1) are partially phenyl groups, and all of R¹s other than the alkenyl groups of the remaining R¹s are methyl groups, is preferable.

Furthermore, for the purpose of imparting oil resistance and/or solvent resistance to the silicone cured product to be obtained, a combination, in which part of the R¹¹s contained in the polyorganosiloxane (A1) are 3,3,3-trifluoropropyl groups and all of the remaining R¹¹s are methyl groups, can be used. In this case, a combination, in which the R¹s in the unit surrounded by n in the formula (1) are partially 3,3,3-trifluoropropyl groups, and all of the R¹s other than the alkenyl groups of the remaining R¹s are methyl groups, is preferable.

When the linear polyorganosiloxane is used as the (A) component in the addition-curable silicone composition in the embodiment of the present invention, one kind may be used or two or more kinds may be used in combination. Further, also as for the polyorganosiloxane (A1), one kind may be used or two or more kinds may be used in combination.

When two or more kinds of polyorganosiloxane (A1) are used, the polyorganosiloxane (A1) may be the one made by mixing two or more kinds of polyorganosiloxane (A1) different in average degree of polymerization and adjusting the viscosity of the mixture. Using the two or more kinds of polyorganosiloxanes different in average degree of polymerization in combination provides advantages that the adjustment to a desired viscosity becomes easy and the range of usable polyorganosiloxanes becomes wider.

(Polyorganosiloxane (A2))

The polyorganosiloxane (A2) represented by the above average unit formula (2) is a polyorganosiloxane having a resin structure (three-dimensional network structure) containing a (R²₃SiO_{1/2}) unit (hereinafter, referred to also as an “M unit”), a (R²₂SiO_{2/2}) unit (hereinafter, referred to also as a “D unit”), a (R²SiO_{3/2}) unit (hereinafter, referred to also as a “T unit”), and a (SiO_{4/2}) unit (hereinafter, referred to also as a “Q unit”) at a ratio of a:b:c:d.

In a structure of each unit of the polyorganosiloxane (A2), a is a positive number, b, c, and d are 0 or positive numbers, and at least one of c and d is a positive number. In short, the M unit and at least one of the T unit and the Q unit are essential units and the D unit is an optional unit.

Note that the relationship among a, b, c, d in the average unit formula (2) preferably satisfies 0<a/(c+d)<3 and 0≦b/(c+d)<2.

A mass average molecular weight of the polyorganosiloxane (A2) measured by a gel permeation chromatography method is preferably within a range of 1,000 to 100,000, and more preferably 2,000 to 30,000. When the mass average molecular weight of the polyorganosiloxane (A2) is within the above-described range, there is no problem in workability due to significantly increased viscosity of the composition, and the mechanical strength after curing is also good.

Note that the polyorganosiloxane (A2) is not limited in property as long as its composition of the siloxane unit is within the above-described range, and may be in a solid state at room temperature (25° C.) or may be in a liquid state having a comparatively high viscosity of, for example, 200 Pa·s or more.

The R² in each siloxane unit contained in the polyorganosiloxane (A2) independently represents in each unit and, when there are a plurality of R²s in the same unit, independently represents in the unit, a substituted or unsubstituted monovalent hydrocarbon group (however, containing none of an aliphatic unsaturated group, an epoxy group, and an alkoxy group) or an alkenyl group. Concrete examples of the R² include the same groups as those of the substituted or unsubstituted monovalent hydrocarbon group or the alkenyl group exemplified as the R¹ in the above polyorganosiloxane (A1). Further, examples of the preferable mode of the R² include the same groups as those exemplified as the R¹.

The polyorganosiloxane (A2) has at least one alkenyl group in one molecule. The polyorganosiloxane (A2) preferably has two or more alkenyl groups in one molecule. And, the polyorganosiloxane (A2), when composed of two or more kinds, preferably has two or more alkenyl groups in one molecule as an average of them. Besides, the number of the alkenyl groups contained in the polyorganosiloxane (A2) is preferably 50 or less. One or more alkenyl groups contained in one molecule in the polyorganosiloxane (A2) may exist in any of the above-described M to T units.

The polyorganosiloxane (A2) has, as R²s other than the alkenyl groups, a plurality (the number obtained by subtracting the number of the above alkenyl groups from the number of all R²s) of R²s (hereinafter, the R² other than the alkenyl group is expressed by “R²¹”) each representing a monovalent unsubstituted or substituted hydrocarbon group (however, containing none of an aliphatic unsaturated group, an epoxy group, and an alkoxy group). In the polyorganosiloxane (A2), the plurality of R²¹s may be the same or different. In the point that the synthesis is easy, these R²¹s are preferably the same. However, according to the physical properties required of a silicone cured product to be obtained, different groups may be introduced in a part of them.

Because synthesis and handling of the polyorganosiloxane (A2) is easy and excellent heat resistance can be obtained, 50% or more of the R²¹s contained in the polyorganosiloxane (A2) are preferably methyl groups, and all of the R²¹s are particularly preferably methyl groups.

Further, for the purpose of adjusting the hardness and elastic modulus of the silicone cured product to be obtained, a combination, in which part of the R²¹s contained in the polyorganosiloxane (A2) are phenyl groups and all of the remaining R²¹s are methyl groups, can be used.

Note that when the polyorganosiloxane (A2) has phenyl groups, the phenyl groups are preferably contained in the polyorganosiloxane (A2) as T units having a phenyl group (hereinafter, referred to as T^{Ph} units). In this case, the ratio of the T^{Ph} units relative to all constituent units in the polyorganosiloxane (A2) is preferably 20 to 60 mol %, and more preferably 30 to 55 mol % from the viewpoint of easy handling workability of the composition before curing and the mechanical strength of the cure product. Note that in this case, the polyorganosiloxane (A2) may have T units other than the T^{Ph} units, but all of the T units are preferably the T^{Ph} units.

Further, when the polyorganosiloxane (A2) contains the T^{Ph} units, the polyorganosiloxane (A2) is preferably composed of the T^{Ph} units, the D units and the M units. Part of the above-described D units are preferably D units (hereinafter, referred to as D^{Vi} units) containing the above-described alkenyl group (for example, a vinyl group). Note that the D^{Vi} unit includes both a case in which two R²s are alkenyl groups (hereinafter, referred to as D^{Vi2}) and a case in which one R² is an alkenyl group (hereinafter, referred to as D^{Vi1}). Generally, the D^{Vi} unit is the D^{Vi1} unit.

It is preferable to use, as the polyorganosiloxane (A2), at least two kinds such as the polyorganosiloxane (A2) containing the T^{Ph} units and containing the D^{Vi} units at a ratio of 10 mol % or less relative to all constituent units and the polyorganosiloxane (A2) containing the T^{Ph} units and containing the D^{Vi} units at a ratio of more than 10 mol %. Use of such two kinds as the polyorganosiloxane (A2) provides an effect of facilitating adjustment of the hardness and elastic modulus of the cured product. Further, in such a case, the (A) component can be constituted of only the polyorganosiloxane (A2) having the resin structure.

When the polyorganosiloxane having the resin structure is used as the (A) component in the addition-curable silicone composition in the embodiment of the present invention, one kind may be used or two or more kinds may be used in combination. Further, also as for the polyorganosiloxane (A2), one kind may be used or two or more kinds may be used in combination.

In the addition-curable silicone composition in the embodiment of the present invention, the (A) component is the polyorganosiloxane containing alkenyl groups being a base polymer. When the linear polyorganosiloxane and the polyorganosiloxane having the resin structure are used in combination as the (A) component, their ratio can be arbitrarily set according to the use.

For example, in the case of fabricating an addition-curable silicone composition used for a member for an optical semiconductor element, when the polyorganosiloxane (A1) and the polyorganosiloxane (A2) are used in combination as the (A) component, the ratio of the polyorganosiloxane (A2) relative to 100 parts by mass of the total amount of the polyorganosiloxane (A1) and the polyorganosiloxane (A2) can be set to 5 to 100 parts by mass. Though depending on the kinds of the polyorganosiloxane (A1) and polyorganosiloxane (A2) used, the above ratio of the polyorganosiloxane (A2) is preferably 5 to 60 parts by mass, and more preferably 10 to 30 parts by mass. The polyorganosiloxane (A1) and the polyorganosiloxane (A2), when the ratio of their contents falls within the above range, can provide optimum hardness and sufficient mechanical strength to the cured product in the above use.

As the polyorganosiloxane (A2) when setting the ratio of the polyorganosiloxane (A2) relative to 100 parts by mass of the total amount of the polyorganosiloxane (A1) and the polyorganosiloxane (A2) to 100 parts by mass in the above, the polyorganosiloxane (A2) made by combining the above-described two kinds of polyorganosiloxane (A2) containing the T^{Ph} units and the D % units is preferable.

[(B) Component]

The polyorganohydrogensiloxane having at least two hydrogen atoms bonded to silicon atoms in one molecule being the (B) component acts as a crosslinking component which reacts with the above-described (A) component. The molecular structure of the (B) component is not particularly limited, and for example, various kinds of polyorganohydrogensiloxanes in linear, cyclic, branched, three dimensional network structure (resin structure), and so on can be used.

The polyorganohydrogensiloxane being the (B) component has two or more hydrogen atoms bonded to silicon atoms, namely, hydrosilyl groups (Si—H groups) in one molecule. The polyorganohydrogensiloxane being the (B) component preferably has three or more Si—H groups in one molecule. When the polyorganohydrogensiloxane being the (B) component is linear, these Si—H groups may be located only at either one of an end and an intermediate part of a molecular chain or may be located at both of them. Note that the number of the Si—H groups mentioned here is an average number per molecule in the polyorganohydrogensiloxane.

An average number of silicon atoms (average degree of polymerization) in one molecule of the (B) component is preferably 2 to 1,000, and more preferably 3 to 100. The viscosity (25° C.) of the (B) component is preferably 500 mPa·s or less, and particularly preferably within a range of 10 to 100 mPa·s. When the viscosity of the (B) component is within this range, workability of a composition to be obtained is good, and physical properties of a silicone cured product to be obtained from this composition are also good.

The amount of the Si—H groups contained in a molecule of the polyorganohydrogensiloxane being the (B) component is preferably 0.3 to 15 mmol/g and more preferably 1 to 10 mmol/g.

As the (B) component, for example, a polyorganohydrogensiloxane represented by the following average composition formula (4) is used.

R⁴ₚH_{q}SiO_{(4-p-q)2} (4)

In the formula (4), R⁴ represents an unsubstituted or substituted monovalent hydrocarbon group having no aliphatic unsaturated group. p and q are positive numbers satisfying 0.7≦p≦2.1, 0.001≦q≦1.0 and (p+q)≦3.0.

Examples of the above R⁴ include: alkyl groups such as a methyl group, an ethyl group, a propyl group, an isopropyl group, a butyl group, an isobutyl group, a t-butyl group, a pentyl group, a neopentyl group, a hexyl group, a cyclohexyl group, an octyl group, a nonyl group, and a decyl group; aryl groups such as s phenyl group, a tolyl group, a xylyl group, and a naphthyl group; aralkyl groups such as a benzyl group, a phenylethyl group and a phenylpropyl group; and groups in which part or all of the hydrogen atoms in the hydrocarbon groups are substituted by halogen atoms, such as a chloromethyl group, a 3-chloropropyl group, a bromoethyl group, and a 3,3,3-trifluoropropyl group. The R⁴ is preferably an alkyl group or an aryl group, more preferably a methyl group or a phenyl group, and particularly preferably a methyl group.

Concrete examples of the (B) component include polyorganohydrogensiloxanes such as a both ends trimethylsiloxy group-terminated methylhydrogenpolysiloxane, a both ends trimethylsiloxy group-terminated dimethylsiloxane/methylhydrogensiloxane copolymer, a both ends trimethylsiloxy group-terminated dimethylsiloxane/methylhydrogensiloxan/diphenylsiloxane copolymer, a both ends dimethylhydrogensiloxy group-terminated dimethylpolysiloxane, a both ends dimethylhydrogensiloxy group-terminated dimethylsiloxane/methylhydrogensiloxane copolymer, a both ends dimethylhydrogensiloxy group-terminated dimethylsiloxane/diphenylsiloxane copolymer, and a both ends dimethylhydrogensiloxy group-terminated diphenylpolysiloxane.

Concrete examples of the (B) component further include polyorganohydrogensiloxanes such as a polyorganosiloxane copolymer composed of an R⁴₃SiO_{1/2} (where the R is as described above, and the following R⁴s are the same) unit, an R⁴₂HSiO_{1/2} unit, and a SiO_{4/2} unit, a polyorganosiloxane copolymer composed of an R⁴₂HSiO_{1/2} unit and a SiO_{4/2} unit or an R⁴SiO_{3/2}, a polyorganosiloxane copolymer composed of an R⁴HSiO_{2/2} unit, an R⁴SiO_{3/2} unit or an HSiO_{3/2} unit, and so on. As for the (B) component, one kind of them can be used independently, or two or more kinds of them can be used in combination.

As the (B) component, particularly, a polymethylhydrogensiloxane having only a methyl group as an organic group which is bonded to a silicon atom, specifically, a polymethylhydrogensiloxane in which all of the R⁴s in the average composition formula (4) are methyl groups is preferable among the above-described polyorganohydrogensiloxanes.

Note that in the case of using, as the (A) component, the polyorganosiloxane (A) containing phenyl groups, specifically, the polyorganosiloxane (A1) in which R¹s other than the alkenyl groups are composed of methyl groups and phenyl groups in the formula (1) or the polyorganosiloxane (A2) in which R²s other than the alkenyl groups are composed of methyl groups and phenyl groups in the formula (2), it is preferable to use the polyorganohydrogensiloxane (B) containing phenyl groups as the (B) component from the viewpoint of compatibility with the (A) component.

The phenyl groups of the polyorganohydrogensiloxane (B) containing phenyl groups are preferably contained in the T units and/or the D units. When the polyorganosiloxane (A) containing phenyl groups is used as the (A) component, specifically, the (B) component preferably contains a polyorganohydrogensiloxane (B) having the T^{Ph} unit or a (C₆H₅)₂SiO_{2/2} unit (hereinafter, referred to as a D^{Ph2} unit), and a (CH₃)₂HSiO_{1/2} unit.

The content of the polyorganohydrogensiloxane being the (B) component in the addition-curable silicone composition in the embodiment of the present invention is an amount such that an amount of the Si—H groups contained in the (B) component is 0.9 to 3.0 mol relative to 1 mol of a total amount of the alkenyl groups (for example, the vinyl groups) contained in the (A) component. The content of the (B) component is an effective amount for curing the (B) component relative to the above (A) component, and the amount of the Si—H groups contained in the (B) component relative to 1 mol of the total amount of the alkenyl groups contained in the (A) component is preferably 1.0 to 2.8 mol, and more preferably 1.1 to 2.5 mol. By containing the above content of the (B) component, in the addition-curable silicone composition in the embodiment of the present invention, curing reaction sufficiently proceeds and a large amount of unreacted Si—H groups never remain in the silicone cured product, so that the physical properties of the silicone cured product to be obtained hardly change over time.

[(C) Component]

The hydrosilylation reaction catalyst being the (C) component is a catalyst accelerating an addition reaction (hydrosilylation reaction) between the alkenyl groups contained in the (A) component and the Si—H groups in the (B) component. Examples of the (C) component include a platinum-based catalyst, a palladium-based catalyst, a rhodium-based catalyst, and the like, and the platinum-based catalyst is preferable from the viewpoint of economical efficiency. As the platinum-based catalyst, for example, a chloroplatinic acid, an alcohol-modified chloroplatinic acid, a coordination compound of a chloroplatinic acid and olefines, a vinylsiloxane or an acetylene compound, and the like can be used. One kind of them can be used independently, or two or more kinds of them can be used in combination.

The content of the (C) component is not particularly limited as long as it is an effective amount as the catalyst of the hydrosilylation reaction, and it can be within a range of 0.1 to 100 ppm, more preferably 1 to 20 ppm, furthermore preferably 1 to 10 ppm when in terms of platinum atoms relative to a total amount (mass) of the (A) component and the (B) component. When the content is within this range, the addition reaction is sufficiently accelerated, resulting in sufficient curing and economical advantage.

In the addition-curable silicone composition in the embodiment of the present invention, predetermined amounts of the polyorganosiloxanes being the (A) component and the (B) component are used in combination with a catalyst amount of the (C) hydrosilylation reaction catalyst, whereby a silicone cured product high in transparency is obtained as a cured product.

[(D) Component]

The addition-curable silicone composition in the embodiment of the present invention contains, as the (D) adhesiveness imparting agent, at least one selected from (D1) an isocyanuric acid derivative having at least one selected from an epoxy group and an alkoxysilyl group and at least one selected from a hydrosilyl group and a crosslinking vinyl group and (D2) a silane or siloxane compound having at least one selected from an epoxy group and an alkoxy group, and having no isocyanuric ring.

The content of the (D) adhesiveness imparting agent in the addition-curable silicone composition is 0.01 to 10 parts by mass relative to 100 parts by mass of the above (A) component, and is preferably 1 to 5 parts by mass. The (D) adhesiveness imparting agent in the above configuration functions to contribute to improvement in adhesiveness, in particular, to plastic of the silicone cured product to be obtained, specifically, PPA (polyphthalamide resin) or the like.

((D1) Component)

As the isocyanuric acid derivative being the (D1) component having at least one selected from an epoxy group and an alkoxysilyl group and at least one selected from a hydrosilyl group and a crosslinking vinyl group, a compound represented by the following formula (D11) is preferable. Hereinafter, the compound represented by the formula (D11) is referred to also as a compound (D11). Further, this also applies to compounds represented by other formulas.

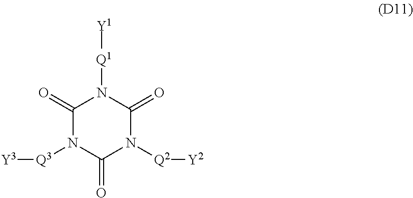

In the formula (D11), each of Y¹ to Y³ independently represents a vinyl group, a methacryloxy group, an acryloxy group, a group represented by the following formula (T1), an alkoxysilyl group, or an epoxy group, one or two of Y¹ to Y³ are vinyl groups, methacryloxy groups, acryloxy groups, or groups represented by the following formula (T1), and the remainder is an alkoxysilyl group or an epoxy group.

The alkoxysilyl group may be any one of an alkoxydialkylsilyl group in which one alkoxy group and two monovalent hydrocarbon groups are bonded to a silicon atom, a dialkoxyalkylsilyl group in which two alkoxy groups and one monovalent hydrocarbon group are bonded to a silicon atom, and a trialkoxysilyl group in which three alkoxy groups are bonded to a silicon atom. The dialkoxyalkylsilyl group and the trialkoxysilyl group are preferable.

As the alkoxy group included in the alkoxysilyl group, an alkoxy group having 1 to 4 carbon atoms that may have a branch structure can be exemplified, and a methoxy group, an ethoxy group, and a propoxy group are preferable, and the methoxy group and the ethoxy group are particularly preferable. As the hydrocarbon group, a hydrocarbon group having 1 to 4 carbon atoms that may have a branch structure can be exemplified, and a methyl group, an ethyl group, and a propyl group are preferable, and the methyl group and the ethyl group are particularly preferable.

Concrete examples of the alkoxysilyl group include a dimethoxymethylsilyl group, a diethoxymethylsilyl group, a trimethoxysilyl group, a triethoxysilyl group and the like.

Each of Q¹ to Q³ is independently a divalent hydrocarbon group having 1 to 7 carbon atoms that may have a linking group represented by the following formula (L1) and may have an ether oxygen atom, between carbon atoms. Note that when the Q¹ to Q³ have the linking group in the following formula (L1), the number of carbons is a number that does not include the number of carbons of the linking group.

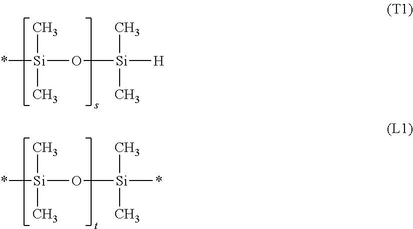

In the formula (T1), s is 1 to 10 and preferably 1 to 4. In the formula (L1), t is 1 to 10 and preferably 1 to 4.

Each of -Q¹-Y¹, -Q²-Y², -Q³-Y³ in (D11) is preferably independently any one of groups shown below.

—(CH₂)ₙ₁-vinyl group (where n1 is an integer from 1 to 4, preferably 1.)

—(CH₂)ₙ₂-epoxy group (where n2 is an integer from 1 to 4, preferably 1.)

—(CH₂)ₙ₃-alkoxysilyl group (where n3 is an integer from 1 to 5, preferably 3.)

—(CH₂)ₙ₄-(T1) (where n4 is an integer from 1 to 5, preferably 3.)

—(CH₂)ₙ₅-(L1)-(CH₂)ₙ₆-glycidoxy group (where n5, n6 are integers from 1 to 5, preferably 3.)

—(CH₂)ₙ₇-(L1)-(CH₂)ₙ₈-alkoxysilyl group (where n7, n8 are integers from 1 to 5, n7 is preferably 3, n8 is preferably 2.)

More concrete examples of the compound represented by (D11) include compounds represented by the following formulas (D11-1) to (D11-7) respectively.

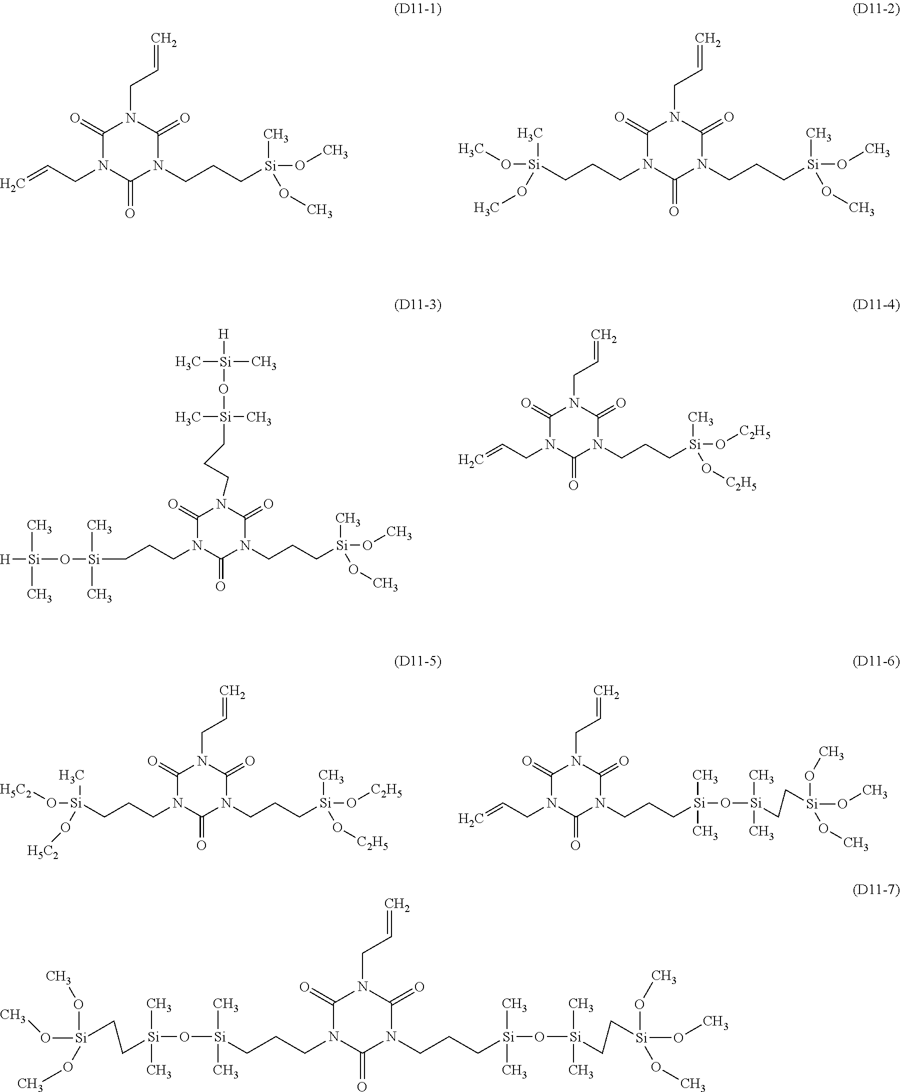

One kind of the (D1) component may be used independently, or two or more kinds may be used in combination. For example, in the compound (D11), a combination of the compound (D11-1) and the compound (D11-2), a combination of the compound (D11-4) and the compound (D11-5), and a combination of the compound (D11-6) and the compound (D11-7) are preferable, and a mixture of each of them at a molar ratio of 1:1 is particularly preferable.

((D2) Component)

The (D2) component being the silane or siloxane compound having at least one selected from an epoxy group and an alkoxy group, and having no isocyanuric ring is preferably at least one selected from a compound represented by the following formula (D21), a compound represented by the formula (D22), a compound represented by the formula (D23), and a following polyorganosiloxane (D24) containing an epoxy group and an alkenyl group.

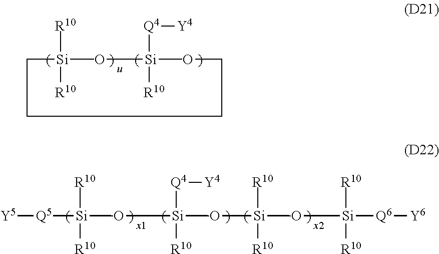

In the formula (D21) and the formula (D22), each of Y⁴, Y⁵, Y⁶ independently represents an epoxy group, a cyclic alkyl group including an epoxy group, or an alkoxysilyl group, each of Q⁴, Q⁵, Q⁶ independently represents a divalent hydrocarbon group having 1 to 10 carbon atoms that may have an ether oxygen atom and an ester bond between carbon atoms, u is 3 to 5, each of x1, x2 is independently 1 to 10, and each R¹⁰ independently represents a hydrogen atom, or an alkyl group or an alkenyl group having 1 20 to 5 carbon atoms that may be substituted by a chlorine atom. However, when a Si—H group exists in the formula (D21) and the formula (D22), the R¹⁰ is a group other than an alkenyl group.

(Y⁷-Q⁷-)ᵥ-SiR⁵_{w}X_{(4-v-w)} (D23)

In the formula (D23), Y⁷ represents an epoxy group or a cyclic alkyl group including an epoxy group, Q⁷ represents a divalent hydrocarbon group having 1 to 10 carbon atoms that may have an ether oxygen atom between carbon atoms, v is 1 or 2, and w is 0 or 1. X represents a hydrolyzable group selected from an alkoxy group and a chlorine atom, and R⁵ represents an alkyl group having 1 to 4 carbon atoms that may be substituted by a chlorine atom, and when a plurality of Xs and (Y⁷-Q⁷-)s exist, they may be the same or different.

Concrete examples of the cyclic alkyl group including an epoxy group represented by Y⁴ to Y⁷ in the above formulas (D21) to (D23) include a 3,4-epoxycyclohexyl group and the like. As the alkoxysilyl groups represented by Y⁴ to Y⁶ in the formulas (D21), (D22) and the —SiR⁵_{w}X_{(4-v-w)} when X is an alkoxy group in (D23), the same groups as the alkoxysilyl groups exemplified when Y¹ to Y³ in the above (D11) are alkoxysilyl groups, can be exemplified.

Each of -Q⁴-Y⁴, -Q⁵-Y⁵, -Q⁶-Y⁶ in (D21) and (D22) is preferably independently any one of groups shown in the following (i) to (iv).

(i) —(CH₂CHCH₃—C(═O)—O—)ₙ₁₁—(CH₂)ₙ₁₂-alkoxysilyl group (where n11 is 1 or 0, n12 is an integer from 1 to 5, preferably 2 or 3.)
(ii) —(CH₂)ₙ₁₃-epoxy group (where n13 is an integer from 1 to 5, preferably 3.)
(iii) —(CH₂)ₙ₁₄-glycidox group (where n14 is an integer from 1 to 5, preferably 3.)
(iv) —(CH₂)ₙ₁₅-(3,4-epoxycyclohexyl group) (where n15 is an integer from 1 to 5, preferably 2.)

As the compound represented by the formula (D21), a compound represented by the following formula (D21-1) can be exemplified.

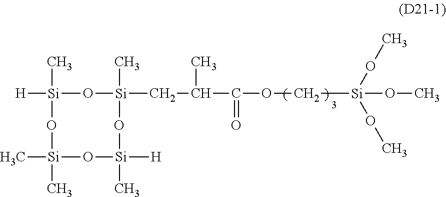

Besides, as the compound represented by the above formula (D23), a compound represented by the following formula (D23-1) can be exemplified.

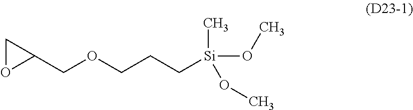

The polyorganosiloxane (D24) containing an epoxy group and an alkenyl group is a polyorganosiloxane that contains a siloxane unit having an epoxy group and a bifunctional siloxane unit having an alkenyl group, and has a mass average molecular weight of 1,000 to 15,000.

The siloxane unit having an epoxy group is at least one selected from a group consisting of a trifunctional siloxane unit (hereinafter, referred to as a T1^{ep} unit) represented by R^{ep}SiO_{3/2}, a bifunctional siloxane unit (hereinafter, referred to as a D1^{ep} unit) represented by R^{ep}R⁶SiO_{2/2}, and a monofunctional siloxane unit (hereinafter, referred to as an M1^{ep} unit) represented by R^{ep}R⁶₂SiO_{1/2}.

In each of the above formulas, R^{ep} represents a monovalent organic group having an epoxy group. Examples of the monovalent organic group having an epoxy group include groups expressed in the above (ii) to (iv) and the like. Among them, the group expressed by (iii) is preferable, and a 3-glycidoxypropyl group is more preferable. R⁶ represents an alkyl group having 1 to 8 carbon atoms or an alkoxy group having 1 to 4 carbon atoms. A methyl group is preferable as the alkyl group, and a methoxy group is preferable as the alkoxy group.

The siloxane unit having an epoxy group only needs to be at least one kind of the above T1^{ep} unit, D1^{ep} unit, and M1^{ep} unit, and preferably contains at least the T1^{ep} unit so that the polyorganosiloxane (D24) to be obtained is less likely to volatilize.

The bifunctional siloxane unit having an alkenyl group is a unit represented by R⁷₂SiO_{2/2} (hereinafter, referred to as a D1^{vi} unit). Note that in the above formula, R⁷ represents a monovalent hydrocarbon group selected among an alkenyl group, an alkyl group having 1 to 8 carbon atoms, and an aryl group having 6 to 9 carbon atoms, and at least one of the two R⁷s is an alkenyl group. Examples of the alkenyl group include a vinyl group, an allyl group, a butenyl group, a pentenyl group, a hexenyl group and the like, and a vinyl group is more preferable. The group other than the alkenyl group of R⁷s is preferably an alkyl group having 1 to 8 carbon atoms, and particularly preferably a methyl group.

The polyorganosiloxane (D24) can further contain a trifunctional siloxane unit (hereinafter, referred to as a T1 unit) represented by R⁸SiO_{3/2} and/or a bifunctional siloxane unit represented by R⁸₂SiO_{2/2} (hereinafter, referred to as a D1 unit) in addition to at least one kind of unit selected among the T1^{ep} unit, D1^{ep} unit, and M1^{ep} unit, and the D1^{vi} unit. The R⁸ in each of the above formulas represents an alkyl group having 1 to 8 carbon atoms or an aryl group having 6 to 9 carbon atoms, and is preferably an alkyl group and is particularly preferably a methyl group.

In the polyorganosiloxane (D24), the constituent ratio among the siloxane units, namely, the molar ratio among at least one selected among the T1^{ep} unit, D1^{ep} unit, and M1^{ep} unit (hereinafter, referred to as a “T1^{ep} unit or the like”), the D1^{vi} unit, and the other units (the T1 unit and/or the D1 unit) is not particularly limited, and the ratio of the T1^{ep} unit or the like is preferably set to 5 to 50 mol % of all units from the viewpoint of imparting adhesiveness. Further, the ratio of the D1^{vi} unit is preferably set to 1 to 40 mol % of all units from the viewpoint of reactivity to the base polymer of the above composition of the present invention.

<Preparation Method of the Polyorganosiloxane (D24)>

The polyorganosiloxane (D24) can be prepared, for example, by the method illustrated below. More specifically, at least one kind of a silane compound having an epoxy group selected among a trifunctional silane represented by R^{ep}Si(OR⁶)₃, a bifunctional silane represented by R^{ep}R⁶Si(OR⁶)₂, and a monofunctional silane represented by R^{ep}R⁶₂Si(OR⁶), a silane compound having an alkenyl group represented by R⁷₂Si(OR)₂, and, when necessary, a trifunctional silane represented by R⁸Si(OR⁶)₃ and/or a bifunctional silane represented by R⁸₂Si(OR⁶)₂, are charged into a reaction container, the liquid is made basic and heated, and subjected to partial hydrolysis and then condensation reaction.

In the above formula, R^{ep} represents a monovalent organic group having an epoxy group, R⁶ represents an alkyl group, R⁷ represents a monovalent hydrocarbon group selected among an alkenyl group, an alkyl group, and an aryl group, and R⁸ represents an alkyl group or an aryl group. As those groups, the same groups as described above can be exemplified. Preferable groups are also the same as described above.

Then, alcohol is distilled off from the obtained reaction mixture, and then the liquid reaction mixture is neutralized. Thereafter, a low-molecular weight component is removed from the reaction mixture, and solvent removal and concentration are performed, whereby the polyorganosiloxane (D24) can be obtained.

The mass average molecular weight of the polyorganosiloxane (D24) thus obtained is set to a range of 1,000 to 15,000. When the mass average molecular weight of the polyorganosiloxane (D24) is less than 1,000, the polyorganosiloxane is likely to volatilize in a heating process when curing the composition having the polyorganosiloxane compounded therein, or due to heat generation after the curing, heating in a temperature cycle or the like, and thus decreases in adhesiveness. Besides when the mass average molecular weight is more than 15,000, the polyorganosiloxane is difficult to uniformly compound into the composition, and thus hardly produces an effect of improving the adhesiveness.

As for the (D2) component, one kind may be used independently, or two or more kinds may be used in combination. It is preferable to combine at least one kind of the compound (D21) and at least one kind of the compound (D23) from the viewpoint of maintaining high adhesiveness and excellent external appearance.

In the addition-curable silicone composition in the embodiment of the present invention, as for the (D) adhesiveness imparting agent, one kind may be used, or two or more kinds may be used in combination. A preferable combination is a combination of at least one kind of the above (D1) isocyanuric acid derivative and at least one kind of the above (D2) silane or siloxane compound. The content ratio between at least one kind of the (D1) isocyanuric acid derivative and at least one kind of the (D2) silane or siloxane compound is preferably 0.1 to 3.0, and more preferably 0.25 to 1.5, as a mass ratio expressed by (D1)/(D2). By containing the (D1) component and the (D2) component at the ratio, the addition-curable silicone composition achieves extremely high adhesiveness in the silicone cured product to be obtained, for example, improved adhesive strength, and becomes to be able to cope with various adhered articles, specifically, metal, in particular, silver and the like. Further, the addition-curable silicone composition can impart excellent external appearance to the silicone cured product to be obtained.

Note that when the compound having a hydrosilyl group and a crosslinking vinyl group is used as the above (D) component, it is preferable to adjust the ratio between the hydrosilyl groups and the alkenyl groups in the whole addition-curable silicone composition to be obtained, namely, the ratio between the total amount of the hydrosilyl groups and the total amount of the alkenyl groups, in the (A) component, the (B) component, and the (D) component, for example, such that an amount of the hydrosilyl groups is 0.9 to 3.0 mol relative to 1 mol of the alkenyl groups. The ratio is preferably 1.0 to 2.8 mol, and more preferably 1.0 to 2.5 mol.

[(E) Component]

The (E) component is the carboxylic acid metal salt represented by the following general formula (3).

(R³COO)ₖM (3)

M represents a metal atom selected among Ce, Fe, Cr, La, Nd, Pr and Sm, k represents a positive number from 2 to 4, and R³ represents a substituted or unsubstituted hydrocarbon group having 4 to 17 carbon atoms.

By containing the carboxylic acid metal salt being the (E) component, the addition-curable silicone composition in the embodiment of the present invention becomes possible to suppress shrinkage and change in hardness due to heat in the silicone cured product to be obtained, caused by the adhesiveness imparting agent being the (D) component. Further, when a metal member, for example, a silver electrode or the like is coated and sealed with the silicone cured product to be obtained, it becomes possible to protect them from corrosion.

In the general formula (3), M represents a metal atom selected among Ce, Fe, Cr, La, Nd, Pr and Sm. M may be composed of one selected among the above Ce, Fe, Cr, La, Nd, Pr and Sm, or may be composed of two or more kinds of them. Concrete examples of a mixture include rare-earth element mixtures of Ce, La, Nd, Pr and Sm, and a mixture containing cerium (Ce) as a main component is preferable. Note that the mixture containing cerium as a main component means a mixture having a content of cerium of more than 50 mass % relative to the total amount of the mixture.

As the carboxylic acid metal salt used as the (E) component, a carboxylic acid metal salt having M in the formula (3) composed of only cerium (Ce), only iron (Fe), or only chromium (Cr) is preferable, and the carboxylic acid metal salt composed of only cerium is particularly preferable. In the case of attaching importance to improvement in corrosion resistance of metal, in particular, silver, the carboxylic acid metal salt composed of only chromium is also preferable. To k, 2 to 4 is given depending on the valence of the metal in use.

R³s are the same kind or different kinds of substituted or unsubstituted monovalent hydrocarbon groups having 4 to 17 carbon atoms, and examples of the carboxylic acid providing such carboxylic acid metal salt include a 2-ethylhexanoic acid, an octanoic acid, a decanoic acid, an oleic acid, a lauric acid, a stearic acid and the like. Further, the carboxylic acid may be a carboxylic acid mixture such as a naphthenic acid or the like.

Concrete examples of the carboxylic acid metal salt include cerium (III) octanoate, cerium (III) 2-ethylhexanoate, iron (II) 2-ethylhexanoate, iron (III) 2-ethylhexanoate, chromium (Ill) 2-ethylhexanoate, cerium (IV) decanoate, cerium (III) decanoate and the like. The cerium (III) octanoate and the cerium (III) 2-ethylhexanoate are particularly preferable. Besides, a salt of an octanoic acid or a 2-ethylhexanoic acid and rare-earth element mixtures containing cerium as a main component can also be preferably used. Use of the rare-earth element mixture containing cerium as a main component is advantageous in point of economic efficiency. The higher content of cerium in the mixture, namely, the higher purity of cerium is more preferable in point of effects of suppressing shrinkage and change in hardness due to heat in the silicone cured product to be obtained. The kind of the carboxylic acid metal salt is appropriately selected in consideration of the economic efficiency and the effects of suppressing shrinkage and change in hardness due to heat in the silicone cured product to be obtained.

As the (E) component, a commercial item may be used. Examples of the commercial item include 12% Cerium Hex-Cem (brand name, manufactured by OMG Americas Inc., metal content: Ce; 12 mass %), Rare Earth-OCTOATE 6% (brand name, manufactured by DIC Corporation, rare-earth element salt of 2-ethylhexanoic acid (rare-earth element content; 6 mass %: Ce; 3.1 mass %, Nd; 0.95 mass %, Pr, 0.31 mass %, Sm; 0.01 mass %, La; 1.59 mass %), Nikka Ok Chicks Iron (brand name, manufactured by NIHON KAGAKU SANGYO CO., LTD., iron (III) 2-ethylhexanoate (metal content: Fe; 6 mass %)), 8% Chromium Hex-Cem (brand name, manufactured by OMG Americas Inc., chromium (III) 2-ethylhexanoate (metal content: Cr, 8 mass %)) and the like.

Note that the carboxylic acid metal salt used as the (E) component, for example, cerium (III) octanoate, cerium (III) 2-ethylhexanoate, rare-earth element salt of 2-ethylhexanoic acid, iron (II), (III) 2-ethylhexanoate, chromium (III) 2-ethylhexanoate, or the like is preferably used as an organic solvent solution from the viewpoint of easy handling and compatibility with other components in the composition. Examples of the organic solvent include petroleum solvents such as a standard solvent, a mineral spirit, ligroin, and petroleum ether, and aromatic solvents such as toluene and xylene.

The content of the carboxylic acid metal salt being the (E) component in the addition-curable silicone composition in the embodiment of the present invention is an amount to be 0.001 to 0.015 parts by mass in terms of metal atoms, namely, as an amount of metal atoms contained in the carboxylic acid metal salt, more preferably 0.002 to 0.012 parts by mass, and more preferably 0.003 to 0.010 parts by mass relative to 100 parts by mass of the (A) component. When the ratio of the content of the (E) component relative to the (A) component is within the above range, it is possible, in the silicone cured product to be obtained, to suppress shrinkage and change in hardness due to heat caused by the (D) component while maintaining excellent external appearance. Further, the silicone cured product to be obtained, in which the action by the (D) component is sufficiently exhibited, can accordingly maintain excellent adhesiveness. Furthermore, it becomes possible to effectively suppress corrosion of metal, in particular, silver which is coated, sealed or the like with the silicone cured product to be obtained, in other words, to protect metal, in particular, silver from corrosion.

[Optional Component—(F) Component]

The addition-curable silicone composition in the embodiment of the present invention may contain, as an optional component, the silica powder being the (F) component. The silica powder being the (F) component only needs to be a publicly-known one which is generally compounded in the silicone cured product. The (F) component has an action to impart proper fluidity, thixotropy to the composition before crosslinking, and impart, to a crosslinked body of the polyorganosiloxane obtained by crosslinking, high mechanical strength which is required according to the use thereof. In particular, when the (A) component is composed of only the linear polyorganosiloxane, for example, the polyorganosiloxane (A1), the addition-curable silicone composition preferably contains the silica powder being the (F) component.

The silica powder being the (F) component preferably has a specific surface area by the BET method (hereinafter, referred to as a BET specific surface area) of 50 m²/g or more, more preferably 50 to 600 m²/g, and particularly preferably 100 to 400 m²/g in order to fulfill the above-described functions. The kind of silica is not particularly limited, and precipitated silica, fumed silica, baked silica, and the like are suitably used. The fumed silica is preferable in point of imparting reinforcement and thixotropy.

On the surface of the silica powder, a lot of silanol groups (Si—OH groups) exist. Therefore, when the silica powder is added as it is to the composition, problems such as increase in viscosity, remarkable plasticization return easily occur. Therefore, it is preferable to perform a hydrophobic treatment for the surface of the silica powder. A surface treatment amount is preferably an amount in which a carbon amount at the silica surface becomes 2.0 mass % or more, and more preferably 3.0 mass % or more. When it is less than 2.0 mass %, there are small effects in suppression of the increase in viscosity of the composition, and improvement in pot life. Note that the upper limit of the carbon amount is not particularly limited, but it is generally 20 mass % or less, preferably 12 mass % or less, and particularly preferably 8 mass % or less. As the silica powder being the (F) component, the one which is surface-treated in advance in a powder state may be used. Besides, the surface treatment on the silica powder may be performed together with kneading in a later-described kneading process.

As the surface treatment method of the silica powder, a generally well-known surface treatment technique can be employed. Examples of an organosilicon compound used as the surface treatment agent include: organosilazanes such as hexaorganodisilazanes such as 1,3-divinyltetramethyldisilazane, 1,3-dimethyltetravinyldisilazane and hexamethyldisilazane, and octaorganotrisilazanes such as octamethyltrisilazane and 1,5-divinylhexamethyltrisilazane; alkyltrialkoxysilanes such as methyltrimethoxysilane, ethyltrimethoxysilane, propyltrimethoxysilane and butyltrimethoxysilane; dialkyldialkoxysilanes such as dimethyldimethoxysilane, diethyldimethoxysilane, dimethyldiethoxysilane and diethyldiethoxysilane; alkenyltrialkoxysilanes such as vinyltriethoxysilane, vinyltrimethoxysilane and vinyltris(methoxyethoxy)silane; dialkenyldialkoxysilanes such as divinyldimethoxysilane and divinyldiethoxysilane; trialkylalkoxysilanes such as trimethylmethoxysilane and triethylmethoxysilane; trialkenylalkoxysilanes such as trivinylmethoxysilane and trivinylethoxysilane; organochlorosilanes such as trimethylchlorosilane, dimethyldichlorosilane, methyltrichlorosilane, vinyltrichlorosilane, divinyldichlorosilane and trivinylchlorosilane; and a silane coupling agent such as chloropropyltrimethoxysilane; dimethylpolysiloxane (including a cyclic structure), organohydrogenpolysiloxane, and the like, or it may be a partial hydrolyzed product thereof. Note that among them, the silane-based coupling agent whose substituent group bonded to a silicon atom other than a hydrolyzable group is a methyl group, the cyclic dimethylpolysiloxane, and the organosilazanes are preferable.

As the silica powder being the (F) component, a commercial item may be used. Examples of the commercial item include, as fumed silica whose surface is untreated, Aerosil 200 (brand name, manufactured by EVONIC, BET specific surface area: 200 m²/g), Aerosil 300 (brand name, manufactured by EVONIC, BET specific surface area: 300 m²/g), and the like. Further, in the present invention, it is preferable to use the silica powder in which such a commercial item is surface treated with an octamethylcyclotetrasiloxane, hexamethyldisilazane, or the like. As for the (F) component, one kind may be used, or two or more kinds may be used in combination.

The content of the (F) component in the composition of the present invention is preferably 10 parts by mass or less relative to 100 parts by mass of the (A) component from the point that the viscosity of the composition can be properly controlled. As described above, when the (A) component is composed of only the polyorganosiloxane (A1), the composition preferably contains the (F) component, and its content is preferably 0.1 to 10 parts by mass relative to 100 parts by mass of the (A) component, and more preferably 1 to 4 parts by mass. When the content of the silica powder being the (F) component is within the above-described range, the viscosity of the composition becomes appropriate and excellent workability at molding is maintained, and sufficient properties such as mechanical strength, hardness and so on of the silicone cured product to be obtained are also maintained.

[Optional Component—(G) Component]

The addition-curable silicone composition in the embodiment of the present invention may further contain, as an optional component, an addition reaction inhibitor as a (G) component. The addition reaction inhibitor being the (G) component acts to prevent the catalytic activity of the hydrosilylation reaction catalyst being the (C) component from decreasing in preservation and suppress the addition reaction between the alkenyl groups of the (A) component and the Si—H groups of the (B) component, thereby enhancing the preservation stability of the addition-curable silicone composition.

As the addition reaction inhibitor, a publicly-known one can be used. Examples thereof include: acetylene-based alcohols such as 1-ethynylcyclohexane-1-ol, 3-methyl-1-butyn-3-ol, 3,5-dimethyl-1-hexyne-3-ol, 3-methyl-1-pentene-3-ol, and phenylbutynol; acetylene-based compounds such as 3-methyl-3-pentene-1-yne and 3,5-dimethyl-1-hexyne-3-yne; reactants of these acetylene-based compounds and alkoxysilane, alkoxysiloxane, hydrogensilane, or hydrogensiloxane; vinyl siloxanes such as a tetramethylvinylsiloxane cyclic form; an organic nitrogen compound such as benzotriazole and other organic phosphorous compounds; and an oxime compound, an organochromium compound, diallyl maleate and the like.

The content of the addition reaction inhibitor being the (G) component is not particularly limited as long as it is an amount to provide the stability of the addition-curable silicone composition, and is preferably 0.001 to 0.1 parts by mass, and more preferably 0.01 to 0.05 parts by mass relative to 100 parts by mass of the (A) component.

Note that the addition-curable silicone composition, for example, when containing the (A) component containing the polyorganosiloxane (A2) having the T^{Ph} unit and the (B) component containing the polyorganohydrogensiloxane (B) having the T^{Ph} unit or the D^{Ph2} unit, is comparatively excellent in preservation stability and therefore may not contain the addition reaction inhibitor being the (G) component.

[Other Optional Components]

The addition-curable silicone composition in the embodiment of the present invention contains the respective components of the above-described (A) to (E) in the above-described contents as the essential components, and contains the (F) component and the (G) component in the above-described contents as the optional components according to need. Further, as optional components, a polyorganosiloxane other than the above, an inorganic filler other than the silica powder being the (F) component such as pulverized silica (quartz fine powder), an aluminum oxide, a conductive filler such as silver powder, a phosphor to obtain a target emission color for use in an optical semiconductor device, an organic solvent such as toluene, xylene, hexane, heptane, ethanol, isopropyl alcohol, acetone, or methyl ethyl ketone, a dye, a pigment, a flame retardant, a heat resistance improver, an anti-oxidation degradation agent, a wavelength adjusting agent, and so on may be added within a range not impairing the effects of the present invention.

The manufacturing method of the addition-curable silicone composition in the embodiment of the present invention is not particularly limited in addition order of the components, and examples thereof include a method of kneading the essential components of the (A) to (E), the (F) component and the (G) component as the optional components which are preferably added, and the above-described other optional components by a well-known kneader, and the like.

Note that when the (E) component is used in the form of the organic solvent solution, it is preferable to mix the (A) component and the (E) component in advance, and then remove the organic solvent from the mixture. In this case, the kneading is performed after adding the remaining components to the mixture after removal of the organic solvent.

Examples of the kneader include a planetary mixer, a three-rollers, a kneader, a Shinagawa mixer, and the like in which a heating unit and a cooling unit are included as needed, and it is possible to use them independently, or in combination.

Curing of the addition-curable silicone composition in the embodiment of the present invention is mainly performed by subjecting the (A) component and the (B) component to a hydrosilylation reaction in the presence of the (C) component. At this time, the curing reaction can be appropriately adjusted in accordance with the kind of the addition reaction inhibitor and the addition amount thereof. Examples of preferable conditions for curing include a condition of heating at 50 to 200° C. for 60 to 300 minutes, and the like. The silicone cured product obtained as described above is a hard rubber state or a resin state having flexibility, and has excellent adhesiveness and external appearance and has suppressed heat shrinkage and change in hardness due to heat. Further, when coating, sealing or the like a metal member, for example, a silver electrode or the like, the silicone cured product has a function to protect them from corrosion.

The addition-curable silicone composition of the present invention is excellent, for example, as a sealant or a die attach agent for COB (chip on board) which is used when mounting and sealing an optical semiconductor chip such as an LED on a substrate. Further, the addition-curable silicone composition can be widely used for a general-purpose optical semiconductor package such as a photodiode, a CCD, a CMOS or the like.

In the optical semiconductor device in which the addition-curable silicone composition of the present invention is used, for example, as a sealant or a die attach agent to seal the optical semiconductor chip, a support structure where the optical semiconductor chip is mounted is not particularly limited, and it may be a package, may be a packageless supporting substrate, for example, a ceramic substrate, a silicon substrate, a glass epoxy substrate, a bakelite (epoxy resin) substrate, a metal substrate, a plastic, specifically, PPA (polyphthalamide resin) substrate or the like. Note that by using the addition-curable silicone composition of the present invention, a silicone cured product with high adhesiveness to the PPA substrate is obtained. It is also possible to make an addition-curable silicone composition which provides a silicone cured product to be obtained according to specifications that is excellent in adhesiveness to metal, for example, silver. Furthermore, it is also possible to protect metal, for example, silver from corrosion by coating or sealing with the silicone cured product.

### EXAMPLES

Hereinafter, examples of the present invention will be described, but the present invention is not limited to these examples. Note that in the following examples, the viscosity is the measured value at 25° C.

In the following examples and comparative examples, as the (A) to (G) components, the following compounds and the like were used. Note that in the following description, Vi represents a vinyl group, Me represents a methyl group, and Ph represents a phenyl group.

(A) Component: Polyorganosiloxane (A1), Polyorganosiloxane (A2)

(Polyorganosiloxane (A1): linear methylvinylpolysiloxane (A11)) A linear methylvinylpolysiloxane represented by an average composition formula; (ViMe₂SiO_{1/2})(Me₂SiO_{2/2})ₘ₁(ViMeSiO_{2/2})ₘ₂(ViMe₂SiO_{1/2}) and having an average degree of polymerization of 450 (m1=448, m2=0), a viscosity of 5000 mPa·s, and the number of vinyl groups per molecule of 2 on average.

(Polyorganosiloxane (A1): Linear Methylvinylpolysiloxane (A12))

A linear methylvinylpolysiloxane represented by an average composition formula; (ViMe₂SiO_{1/2})(Me₂SiO_{2/2})ₘ₃(ViMeSiO_{2/2})ₘ₄(ViMe₂SiO_{1/2}) and having an average degree of polymerization of 89 (m3=75, m4=12), a viscosity of 200 mPa·s, and the number of vinyl groups per molecule of 12 on average.

(Polyorganosiloxane (A2): Methylvinylpolysiloxane Resin (A21))

A methylvinylpolysiloxane resin composed of a Me₃SiO_{1/2} unit, a ViMeSiO_{2/2} unit, and a SiO_{4/2} unit and having a mass average molecular weight of 12,000, the number of vinyl groups per molecule of 12 on average.

(Polyorganosiloxane (A2): Methylphenylvinylpolysiloxane Resin (A22))

A methylphenylvinylpolysiloxane resin represented by an average unit formula; (PhSiO_{3/2})_{47.07}(Ph₂SiO_{2/2})_{15.23}(Me₂SiO_{2/2})_{22.63}(ViMeSiO_{2/2})_{15.04}(ViMe₂SiO_{1/2})_{0.03} and having a mass average molecular weight of 2,450, a solid state, and the number of vinyl groups per molecule of 3.1 (1.25 mmol/g) on average.

(Polyorganosiloxane (A2): Methylphenylvinylpolysiloxane Resin (A23))

A methylphenylvinylpolysiloxane resin represented by an average unit formula; (PhSiO_{3/2})_{39.99}(Ph₂SiO_{2/2})_{12.94}(Me₂SiO_{2/2})_{32.32}(ViMeSiO_{2/2})_{14.68}(ViMe₂SiO_{1/2})_{0.07} and having a mass average molecular weight of 2,150, a viscosity of 30.5 Pa·s, and the number of vinyl groups per molecule of 2.8 (1.29 mmol/g) on average.

(Polyorganosiloxane (A2): Methylphenylvinylpolysiloxane Resin (A24))

A methylphenylvinylpolysiloxane resin represented by an average unit formula; (PhSiO_{3/2})_{46.62}(Ph₂SiO_{2/2})_{15.09}(Me₂SiO_{2/2})_{29.29}(ViMeSiO_{2/2})_{8.95}(ViMe₂SiO_{1/2})_{0.05} and having a mass average molecular weight of 2,150, a viscosity of 300 Pa·s, and the number of vinyl groups per molecule of 1.6 (0.75 mmol/g) on average.

(B) Component

(Linear Methylhydrogenpolysiloxane (B1))

A linear methylhydrogenpolysiloxane represented by an average composition formula; (Me₃SiO_{1/2})(HMeSiO_{2/2})ₘ₅(Me₂SiO_{2/2})ₘ₆(Me₃SiO_{1/2}) and having an average degree of polymerization of 41 (m5=23, m6=16), a viscosity of 20 mPa·s, and the number of Si—H groups per molecule of 24 (8.8 mmol/g) on average.

(Methylphenylhydrogenpolysiloxane Resin (B2))

A methylphenylhydrogenpolysiloxane resin represented by a composition formula; (HMe₂SiO_{1/2})₆(PhSiO_{3/2})₄ and having the number of Si—H groups per molecule of 6 (6.5 mmol/g).

(Linear Methylphenylhydrogenpolysiloxane (B3))

A both ends dimethylhydrogensiloxy group-terminated diphenylpolysiloxane being a 1,1,5,5-tetramethyl-3,3-diphenyltrisiloxane, having a composition formula; (HMe₂SiO_{1/2})₂(Ph₂SiO₂n) and the number of Si—H groups per molecule of 2 (6.0 mmol/g).

(C) Component: Hydrosilylation Reaction Catalyst

A complex of chloroplatinic acid and a divinyltetramethyldisiloxane (referred to simply as “platinum catalyst”).

(D) Component: Adhesiveness Imparting Agent (D1), Adhesiveness Imparting agent (D2)

As the adhesiveness imparting agent (D1), the above compounds (D11-1) to (D11-7) were used.

As the adhesiveness imparting agent (D2), the above compounds (D21-1), (D23-1) and a compound (D24-1) obtained in the following Synthesis example 1 were used.

### Synthesis Example 1

In a 2-L reaction container, 185.9 g (0.788 mol) of 3-glycidoxypropyltrimethoxysilane, 347.1 g (2.888 mol) of dimethyldimethoxysilane, 178.5 g (1.313 mol) of methyltrimethoxysilane, 34.7 g (0.263 mol) of methylvinyldimethoxysilane, and 105 g of toluene were charged, and then 1.02 g of 6N sodium hydroxide (NaOH) aqueous solution, and 53 g of ion-exchange water were put thereinto and stirred.

When a mixture in the reaction container was heated until the liquid temperature became 30° C., a partial hydrolysis reaction of methoxy groups of the above-described four kinds of silane compounds charged as the starting materials (the 3-glycidoxypropyltrimethoxysilane, the dimethyldimethoxysilane, the methyltrimethoxysilane, and the methylvinyldimethoxysilane) was started to start heat generation. Even after the heating was stopped, the heat generation continued, and the reaction mixture became transparent and increased in temperature up to 50° C. The stirring was continued, and at the point when the temperature started to decrease, 60 g of ion-exchange water was added, and the partial hydrolysis reaction was further continued. After the addition of the ion-exchange water, the reaction mixture immediately became transparent and uniform and started heat generation, and increased in temperature up to 60° C. Thereafter, the inside of the reaction container was heated to a reflux temperature (66° C.) using an oil bath. Then, the heating reflux state was continued for 1 hour, and the reaction mixture was then cooled down to room temperature.

Subsequently, 500 g of toluene was added to the obtained reaction mixture, and they were heated again up to the reflux temperature, and methanol being a reaction product was distilled off together with toluene. When the distillation off of methanol was completed and the reaction mixture was brought into the reflux state at a boiling point temperature of toluene, the reaction mixture was cooled and returned to room temperature.

To the reaction mixture thus obtained, 0.72 g of glacial acetic acid was added and they were stirred for 1 hour to neutralize the previously added sodium hydroxide. Thereafter, while the reaction mixture was being heated to the reflux temperature again using the oil bath, nitrogen was flowed into the reaction container to remove a solvent under a reduced pressure of 80° C./25 mmHg, and concentration was performed until a distilled matter was no longer produced. Then, the liquid in the reaction container was cooled, and then subjected to filtration using Celite (manufactured by World Minerals Inc. in USA, brand name), whereby the compound (D24-1) was obtained. The copolymerization composition ratio of the compound (D24-1) was measured by using deuterochloroform as a solvent and using ¹H-NMR (manufactured by BURKER Corporation, apparatus name; ARX-400). As a result of the measurement, the molar ratio among the units, T1^{ep} unit:T1 unit:D1 unit:D1^{vi} unit:methoxy group was 15:25:55:4.5. The mass average molecular weight was 7,455, the viscosity was 321 mPa·s, and the epoxy group content was 1.12 mmol/g.

(E) Component: Carboxylic Acid Metal Salt

Cerium (III) 2-ethylhexanoate (12% Cerium Hex-Cem (brand name, manufactured by OMG Americas Inc., metal content: Ce; 12 mass %, composition: cerium (III) 2-ethylhexanoate; 49 mass %, 2-ethylhexanoic acid; 48 mass %, dipropylene glycol monomethyl ether, 3 mass %) was used.)

Rare-earth element salt of 2-ethylhexanoic acid (Rare Earth-OCTOATE 6% (brand name, manufactured by DIC Corporation, rare-earth element content 6 mass %: Ce; 3.1 mass %, Nd; 0.95 mass %, Pr; 0.31 mass %, Sm; 0.01 mass %, La; 1.59 mass %)) Iron (III) 2-ethylhexanoate (Nikka Ok Chicks Iron (brand name, manufactured by NIHON KAGAKU SANGYO CO., LTD., metal content: Fe; 6 mass %))

Chromium (III) 2-ethylhexanoate (8% Chromium Hex-Cem (brand name, manufactured by OMG Americas Inc., metal content: Cr; 8 mass %, composition: chromium (III) 2-ethylhexanoate; 40 mass %, 2-ethylhexanoic acid; 24 mass %, Distillates(Petroleum), Hydrotreated middle CAS 64742-46-7; 20 mass %, chromium acetate; 16 mass %) was used.)

(F) Component: Silica Powder

Silica powder (F1): fumed silica surface-treated with hexamethyldisilazane having a specific surface area of about 200 m²/g. The carbon amount at the silica surface is 2.5 mass %.

(G) Component: Addition Reaction Inhibitor

Diallyl maleate (manufactured by Tokyo Chemical Industry Co., Ltd., purity: 97 mass % or more)

### Examples 1 to 26, Comparative Examples 1 to 8

Respective components were mixed at compositions listed in Tables 1 to 5 in the following procedure to manufacture addition-curable silicone compositions in Examples 1 to 22 and Comparative examples 1 to 7. Respective components were mixed at compositions listed in Table 6 in the following procedure to manufacture addition-curable silicone compositions in Examples 23 to 26 and Comparative example 8.

The (E) component in the form of the above organic solvent solution was added to the (A) component and mixed, and heated under a reduced pressure (4 mmHg) at 120° C. for 2 hours to remove the organic solvent. Then, other components were added to the mixture and well kneaded, and subjected to deaeration, whereby an addition-curable silicone composition was obtained. When the (E) component was not used, the removal of the organic solvent was not performed, but all of the components were kneaded and subjected to deaeration, whereby an addition-curable silicone composition was obtained.

Note that the content of the (C) component in Tables 1 to 6 is a content (ppm) in terms of platinum atoms relative to a total mass of the (A) component and the (B) component. Besides, the part by mass of the (E) component is the part by mass of the (E) component in terms of metal atoms. In Tables 1 to 6, the Si—H group of the (B) component/the total Vi group of the (A) component (molar ratio), and the Si—H groups/the Vi groups (molar ratio) in the whole composition, namely, by the (A) component, the (B) component, and the (D) component, are listed.

[Evaluation]

Subsequently, the addition-curable silicone compositions obtained in Examples 1 to 26 and Comparative examples 1 to 8 were cured by the following method to fabricate silicone cured product test pieces, and the obtained cured product test pieces were subjected to measurement of initial hardness (TYPE A) and mass by the following methods and thereby subjected to evaluation of external appearance. Subsequently, the silicone cured product test pieces were let stand in a high-temperature atmosphere, and then similarly subjected to measurement of hardness (TYPE A) and mass and thereby subjected to evaluation of hardness (TYPE A) change and mass change.

Further, silicone cured products were formed using the addition-curable silicone compositions obtained in the examples, on the PPA substrate by the following method, and subjected to evaluation of adhesiveness. Further, their corrosion resistance of Ag electrode when the silicone cured products were used in the LED chip mounting package was evaluated. The results are listed at the bottom in Tables 1 to 6. Some examples and comparative examples of them were subjected to evaluation of adhesiveness to the Ag substrate. The results are listed in Table 7.

(Fabrication of Silicone Cured Product Test Piece)

Each of the compositions obtained in the above was cured under the conditions of 150° C. for 60 minutes, whereby a block-shaped test piece of 60×25×6 mm for evaluation was obtained. The obtained test piece was subjected to measurement of hardness (TYPE A) and mass and thereby subjected to evaluation of external appearance.

[Hardness]

The obtained test piece of the cured product was subjected to measurement of hardness (TYPE A) at 25° C. by a type A hardness meter according to JIS K6249. Note that the range of an error in obtained hardness (TYPE A) is ±1.

[Mass]

The obtained test piece of the cured product was subjected to measurement of mass using an electronic analyzing balance (product name: AEU-210, manufactured by Shimadzu Corporation). The range of an error in obtained mass is ±0.001 g, and the range of an error in mass change rate (%) is ±0.01%.

[External Appearance]

The obtained test piece of the cured product was subjected to evaluation of external appearance, based on the following criteria.

◯: It is transparent.
Δ: It is slight cloudy.
x: It is cloudy.

(Higher-Temperature Test)

The silicone cured product test piece after being subjected to the above measurement of initial hardness and mass was let stand in a high-temperature atmosphere at 200° C. for 10 days, and then subjected to measurement of hardness (TYPE A) and mass similarly to the above.

[Hardness Change, Hardness Change Rate, Mass Change Rate]

A value obtained by subtracting the initial hardness (Hi) from the hardness after high-temperature test (Hh) was regarded as a hardness change. Further, (hardness after high-temperature test−initial hardness)/initial hardness×100 was obtained as a hardness change rate (%). Furthermore, (mass after high-temperature test−initial mass)/initial mass×100 was obtained as a mass change rate (%). Note that the mass change rate is an index for measuring the shrinkage due to heat, and a smaller mass change rate indicates smaller heat shrinkage.

[Measurement of Adhesiveness to PPA]

On the surface of the substrate made of PPA, the addition-curable silicone composition obtained in each of the above examples was applied to have a length of 50 mm, a width of 10 mm, and a thickness of 1 mm, and cured under the conditions of 150° C. for 60 minutes. Thereafter, the silicone cured product was scraped off from the substrate surface with a metal spatula, and the state of peeling of the cured product in this event was investigated. Then, the adhesiveness was evaluated based on the following criteria.

◯: The cured product cannot be peeled off from the interface (surface) of the base material and the cured product is broken.
Δ: A part of the cured product is peeled off from the interface (surface) of the base material and a part of the cured product is broken.
x: The cured product can be peeled off from the interface (surface) of the base material.

[Evaluation of Corrosion Resistance of Silver (Ag)]

A 5050PKG-type package (5 mm×5 mm×0.8 mm) mounted with an LED chip having a lead frame made of copper in which a silver layer with a thickness of 10 μm was covered in the form of a wiring conductor at the cavity bottom of an LED chip mounting part was prepared. In this package, the LED chip is a blue-light emitting (InGaN) LED chip, and a bonding wire (gold wire) is connected from an electrode of the LED chip to the silver layer (wiring conductor). Into the cavity of the LED package, the addition-curable silicone composition obtained in each of the above examples was injected and let stand in a thermostatic oven at 150° C. for 60 minutes and thereby cured to fabricate an LED light emitting device, which was used for evaluation.

The LED light emitting device emitted light at 20 mA. In a state where current was applied to the LED light emitting device to cause it to emit light, the LED light emitting device was let stand in a thermohygrostat at temperature and humidity of 85° C., 85 RH % for 30 days to 90 days. Note that the numbers of standing days were depending on examples and comparative examples. The LED light emitting device was taken out after 30 days, after 60 days, and after 90 days according to the number of standing days, and the surface of the silver layer was visually observed and evaluated based on the following criteria.

◯: Corrosion is hardly observed on the surface of the silver layer.
x: Corrosion changed into black or yellow is observed on the surface of the silver layer.

However, in Comparative example 4, impossibility of observation due to peeling was indicated by “x”

TABLE 1

| | | | | Example | | | | | |
|---|---|---|---|---|---|---|---|---|---|
| | Component | | Compound or the like | 1 | 2 | 3 | 4 | 5 | 6 |
| Composition | (A) | (A1) | Linear methylvinylpolysiloxane (A11) | 72.2 | 72.2 | 72.2 | 72.2 | 72.2 | 72.2 |
| (part by mass) | | | Linear methylvinylpolysiloxane (A12) | — | — | — | — | — | — |
| | | (A2) | Methylvinylpolysiloxane resin(A21) | 27.8 | 27.8 | 27.8 | 27.8 | 27.8 | 27.8 |
| | (B) | Linear methylhydrogenpolysiloxane (B1) | | 6.9 | 6.9 | 6.9 | 6.9 | 6.9 | 6.9 |
| | (C) | Platinum catalyst (in terms of platinum ppm | | 5 | 5 | 5 | 5 | 5 | 5 |
| | | relative to (A) + (B)) | | | | | | | |
| | (D) | (D1) | 1:1 (mol) mixture of compound (D11-1) | 0.5 | — | — | — | 0.5 | — |
| | | | and compound (D11-2) | | | | | | |
| | | | Compound (D11-3) | — | — | — | 0.5 | — | — |
| | | | 1:1 (mol) mixture of compound (D11-4) | — | 0.5 | — | — | — | — |
| | | | and compound (D11-5) | | | | | | |
| | | | 1:1 (mol) mixture of compound (D11-6) | — | — | 0.5 | — | — | — |
| | | | and compound (D11-7) | | | | | | |
| | | (D2) | Compound (D21-1) | 1.0 | 1.0 | 1.0 | 1.0 | 1.0 | 1.5 |
| | | | Compound (D23-1) | 0.5 | 0.5 | 0.5 | 0.5 | 0.5 | 0.5 |

| (D1)/(D2) mass ratio | | 0.33 | 0.33 | 0.33 | 0.33 | 0.33 | — |
|---|---|---|---|---|---|---|---|
| (E) | Cerium (III) 2-ethylhexanoate (in terms of Ce) | 0.003 | 0.003 | 0.003 | 0.003 | — | 0.003 |
| | Rare-earth element salt of 2-ethylhexanoic acid | — | — | — | — | — | — |
| | (in terms of rare-earth metal atoms) | | | | | | |
| | Iron (III) 2-ethylhexanoate (in terms of Fe) | — | — | — | — | 0.01 | — |
| | Chromium (III) 2-ethylhexanoate (in terms of Cr) | — | — | — | — | — | — |
| (F) | Silica powder (F1) | — | — | — | — | — | — |
| (G) | Diallyl maleate | 0.03 | 0.03 | 0.03 | 0.03 | 0.03 | 0.03 |

| H bonded to Si of (B)/total Vi group of (A) (molar ratio) | | | 1.9 | 1.9 | 1.9 | 1.9 | 1.9 | 1.9 |
|---|---|---|---|---|---|---|---|---|
| H bonded to Si/Vi group in whole composition by (A), (B), (D) | | | 1.9 | 1.9 | 1.9 | 2.1 | 1.9 | 2.1 |
| components (molar ratio) | | | | | | | | |
| Evaluation | Initial value | Hardness (Type A) (Hi) | 48 | 48 | 48 | 48 | 48 | 47 |
| | | Adhesiveness (PPA resin substrate) | ◯ | ◯ | ◯ | ◯ | ◯ | ◯ |
| | | External appearance | ◯ | ◯ | ◯ | ◯ | ◯ | ◯ |
| | After | Hardness (Type A) (Hh) | 62 | 62 | 60 | 61 | 62 | 59 |
| | high-temperature | Difference in hardness (Hh − Hi) | 14 | 14 | 12 | 13 | 14 | 12 |
| | test (200° C., | Hardness change rate (%) | 29 | 29 | 25 | 27 | 29 | 26 |
| | 10 days) | ((Hh − Hi)/Hi × 100) | | | | | | |
| | | Mass change rate (%) | −1.48 | −1.62 | −1.57 | −1.46 | −2.16 | −1.70 |
| | Silver (Ag) | (85° C., 85 RH %, 30 days) | ◯ | ◯ | ◯ | ◯ | ◯ | ◯ |
| | corrosion | (85° C., 85 RH %, 60 days) | ◯ | ◯ | ◯ | ◯ | ◯ | ◯ |
| | resistance test | | | | | | | |

TABLE 2

| | | | | Example | | | | |
|---|---|---|---|---|---|---|---|---|
| | Component | | Compound or the like | 7 | 8 | 9 | 10 | 11 |
| Composition | (A) | (A1) | Linear methylvinylpolysiloxane (A11) | 72.2 | 72.2 | 72.2 | 72.2 | 81.1 |
| (part by mass) | | | Linear methylvinylpolysiloxane (A12) | — | — | — | — | — |
| | | (A2) | Methylvinylpolysiloxane resin(A21) | 27.8 | 27.8 | 27.8 | 27.8 | 18.9 |
| | (B) | Linear methylhydrogenpolysiloxane (B1) | | 6.9 | 6.9 | 6.9 | 6.9 | 3.8 |
| | (C) | Platinum catalyst (in terms of platinum ppm | | 5 | 5 | 5 | 5 | 5 |
| | | relative to (A) + (B)) | | | | | | |
| | (D) | (D1) | 1:1 (mol) mixture of compound (D11-1) | — | — | — | 0.5 | — |
| | | | and compound (D11-2) | | | | | |
| | | | Compound (D11-3) | — | — | — | — | — |
| | | | 1:1 (mol) mixture of compound (D11-4) | — | — | — | — | — |
| | | | and compound (D11-5) | | | | | |
| | | | 1:1 (mol) mixture of compound (D11-6) | — | — | — | — | — |
| | | | and compound (D11-7) | | | | | |
| | | (D2) | Compound (D21-1) | 1.5 | 1.5 | 1.5 | — | 1.4 |
| | | | Compound (D23-1) | 0.5 | 0.5 | 0.5 | 0.5 | 0.5 |

| (D1)/(D2) mass ratio | | — | — | — | 1.00 | — |
|---|---|---|---|---|---|---|
| (E) | Cerium (III) 2-ethylhexanoate (in terms of Ce) | 0.005 | 0.006 | — | 0.01 | 0.01 |
| | Rare-earth element salt of 2-ethylhexanoic acid | — | — | — | — | — |
| | (in terms of rare-earth metal atoms) | | | | | |
| | Iron (III) 2-ethylhexanoate (in terms of Fe) | — | — | — | — | — |
| | Chromium (III) 2-ethylhexanoate (in terms of Cr) | — | — | 0.002 | — | — |
| (F) | Silica powder (F1) | — | — | — | — | — |
| (G) | Diallyl maleate | 0.03 | 0.03 | 0.03 | 0.03 | 0.03 |

| H bonded to Si of (B)/total Vi group of (A) (molar ratio) | | | 1.9 | 1.9 | 1.9 | 1.9 | 1.4 |
|---|---|---|---|---|---|---|---|
| H bonded to Si/Vi group in whole composition by (A), (B), (D) | | | 2.1 | 2.1 | 2.1 | 1.8 | 1.7 |
| components (molar ratio) | | | | | | | |
| Evaluation | Initial value | Hardness (Type A) (Hi) | 47 | 47 | 47 | 49 | 31 |
| | | Adhesiveness (PPA resin substrate) | ◯ | ◯ | ◯ | Δ | ◯ |
| | | External appearance | ◯ | ◯ | ◯ | ◯ | ◯ |
| | After | Hardness (Type A) (Hh) | 58 | 57 | 61 | 60 | 41 |
| | high-temperature | Difference in hardness (Hh − Hi) | 11 | 10 | 14 | 11 | 10 |
| | test (200° C., | Hardness change rate (%) | 23 | 21 | 30 | 22 | 32 |
| | 10 days) | ((Hh − Hi)/Hi × 100) | | | | | |
| | | Mass change rate (%) | −1.68 | −1.74 | −1.93 | −1.37 | −1.61 |
| | Silver (Ag) | (85° C., 85 RH %, 30 days) | ◯ | ◯ | ◯ | ◯ | ◯ |
| | corrosion | (85° C., 85 RH %, 60 days) | ◯ | ◯ | ◯ | ◯ | ◯ |
| | resistance test | | | | | | |

TABLE 3

| | | | | Example | | | | | |
|---|---|---|---|---|---|---|---|---|---|
| | Component | | Compound or the like | 12 | 13 | 14 | 15 | 16 | 17 |
| Composition | (A) | (A1) | Linear methylvinylpolysiloxane (A11) | 72.2 | 91.0 | 91.0 | 72.2 | 72.2 | 72.2 |
| (part by mass) | | | Linear methylvinylpolysiloxane (A12) | — | 9.0 | 9.0 | — | — | — |
| | | (A2) | Methylvinylpolysiloxane resin(A21) | 27.8 | — | — | 27.8 | 27.8 | 27.8 |
| | (B) | Linear methylhydrogenpolysiloxane (B1) | | 6.9 | 4.5 | 4.5 | 6.9 | 6.9 | 6.9 |
| | (C) | Platinum catalyst (in terms of platinum ppm | | 5 | 3 | 3 | 5 | 5 | 5 |
| | | relative to (A) + (B)) | | | | | | | |
| | (D) | (D1) | 1:1 (mol) mixture of compound (D11-1) | 0.5 | 0.5 | — | 1.6 | 0.5 | — |
| | | | and compound (D11-2) | | | | | | |
| | | | Compound (D11-3) | — | — | — | — | — | — |
| | | | 1:1 (mol) mixture of compound (D11-4) | — | — | 0.5 | — | — | — |
| | | | and compound (D11-5) | | | | | | |
| | | | 1:1 (mol) mixture of compound (D11-6) | — | — | — | — | — | — |
| | | | and compound (D11-7) | | | | | | |
| | | (D2) | Compound (D21-1) | 1.0 | 1.0 | 1.0 | — | 1.5 | 1.5 |
| | | | Compound (D23-1) | 0.5 | 0.5 | 0.5 | — | — | 0.5 |

| (D1)/(D2) mass ratio | | 0.33 | 0.33 | 0.33 | — | 0.33 | — |
|---|---|---|---|---|---|---|---|
| (E) | Cerium (III) 2-ethylhexanoate (in terms of Ce) | 0.003 | 0.003 | 0.005 | 0.005 | 0.01 | 0.01 |
| | Rare-earth element salt of 2-ethylhexanoic acid | — | — | — | — | — | — |
| | (in terms of rare-earth metal atoms) | | | | | | |
| | Iron (III) 2-ethylhexanoate (in terms of Fe) | — | — | — | — | — | — |
| | Chromium (III) 2-ethylhexanoate (in terms of Cr) | — | — | — | — | — | — |
| (F) | Silica powder (F1) | 2.0 | 2.0 | 2.0 | — | — | — |
| (G) | Diallyl maleate | 0.03 | 0.02 | 0.02 | 0.03 | 0.03 | — |

| H bonded to Si of (B)/total Vi group of (A) (molar ratio) | | | 1.9 | 1.8 | 1.8 | 1.9 | 1.9 | 1.9 |
|---|---|---|---|---|---|---|---|---|
| H bonded to Si/Vi group in whole composition by (A), (B), (D) | | | 1.9 | 1.8 | 1.8 | 1.5 | 1.9 | 2.1 |
| components (molar ratio) | | | | | | | | |
| Evaluation | Initial value | Hardness (Type A) (Hi) | 49 | 30 | 29 | 45 | 47 | 46 |
| | | Adhesiveness (PPA resin substrate) | ◯ | ◯ | ◯ | Δ | Δ | ◯ |
| | | External appearance | ◯ | ◯ | ◯ | Δ | ◯ | ◯ |
| | After | Hardness (Type A) (Hh) | 62 | 36 | 35 | 62 | 62 | 59 |
| | high-temperature | Difference in hardness (Hh − Hi) | 13 | 6 | 6 | 17 | 15 | 13 |
| | test (200° C., | Hardness change rate (%) | 27 | 20 | 21 | 38 | 32 | 28 |
| | 10 days) | ((Hh − Hi)/Hi × 100) | | | | | | |
| | | Mass change rate (%) | −1.56 | −0.54 | −0.60 | −1.40 | −1.34 | −1.41 |
| | Silver (Ag) | (85° C., 85 RH %, 30 days) | ◯ | ◯ | ◯ | ◯ | ◯ | ◯ |
| | corrosion | (85° C., 85 RH %, 60 days) | ◯ | ◯ | ◯ | ◯ | ◯ | ◯ |
| | resistance test | | | | | | | |

TABLE 4

| | | | | Example | | | | |
|---|---|---|---|---|---|---|---|---|
| | Component | | Compound or the like | 18 | 19 | 20 | 21 | 22 |
| Composition | (A) | (A1) | Linear methylvinylpolysiloxane (A11) | 72.2 | 72.2 | 72.2 | 72.2 | 72.2 |
| (part by mass) | | | Linear methylvinylpolysiloxane (A12) | — | — | — | — | — |
| | | (A2) | Methylvinylpolysiloxane resin(A21) | 27.8 | 27.8 | 27.8 | 27.8 | 27.8 |
| | (B) | Linear methylhydrogenpolysiloxane (B1) | | 6.9 | 6.9 | 5.4 | 6.5 | 6.9 |
| | (C) | Platinum catalyst (in terms of platinum ppm | | 5 | 5 | 5 | 5 | 5 |
| | | relative to (A) + (B)) | | | | | | |
| | (D) | (D1) | 1:1 (mol) mixture of compound (D11-1) | — | 0.5 | 0.5 | 0.5 | — |
| | | | and compound (D11-2) | | | | | |
| | | | Compound (D11-3) | — | — | — | — | — |
| | | | 1:1 (mol) mixture of compound (D11-4) | — | — | — | — | — |
| | | | and compound (D11-5) | | | | | |
| | | | 1:1 (mol) mixture of compound (D11-6) | — | — | — | — | — |
| | | | and compound (D11-7) | | | | | |
| | | (D2) | Compound (D21-1) | — | 1.0 | 1.0 | 1.0 | 1.5 |
| | | | Compound (D23-1) | 2.0 | 0.5 | 0.5 | 0.5 | 0.5 |

| (D1)/(D2) mass ratio | | — | 0.33 | 0.33 | 0.33 | — |
|---|---|---|---|---|---|---|
| (E) | Cerium (III) 2-ethylhexanoate (in terms of Ce) | 0.01 | — | — | — | — |
| | Rare-earth element salt of 2-ethylhexanoic acid | — | 0.003 | 0.005 | 0.005 | 0.01 |
| | (in terms of rare-earth metal atoms) | | | | | |
| | Iron (III) 2-ethylhexanoate (in terms of Fe) | — | — | — | — | — |
| | Chromium (III) 2-ethylhexanoate (in terms of Cr) | — | — | — | — | — |
| (F) | Silica powder (F1) | — | — | — | — | — |
| (G) | Diallyl maleate | — | 0.03 | 0.03 | 0.03 | 0.03 |

| H bonded to Si of (B)/total Vi group of (A) (molar ratio) | | | 1.9 | 1.9 | 1.5 | 1.8 | 1.9 |
|---|---|---|---|---|---|---|---|
| H bonded to Si/Vi group in whole composition by (A), (B), (D) | | | 1.9 | 1.9 | 1.5 | 1.8 | 2.1 |
| components (molar ratio) | | | | | | | |
| Evaluation | Initial value | Hardness (Type A) (Hi) | 49 | 48 | 46 | 48 | 47 |
| | | Adhesiveness (PPA resin substrate) | ◯ | ◯ | ◯ | ◯ | ◯ |
| | | External appearance | ◯ | ◯ | ◯ | ◯ | Δ |
| | After | Hardness (Type A) (Hh) | 60 | 63 | 61 | 64 | 60 |
| | high-temperature | Difference in hardness (Hh − Hi) | 11 | 15 | 15 | 16 | 13 |
| | test (200° C., | Hardness change rate (%) | 22 | 31 | 33 | 33 | 28 |
| | 10 days) | ((Hh − Hi)/Hi × 100) | | | | | |
| | | Mass change rate (%) | −1.95 | −1.74 | −1.64 | −1.68 | −1.44 |
| | Silver (Ag) | (85° C., 85 RH %, 30 days) | ◯ | ◯ | ◯ | ◯ | ◯ |
| | corrosion | (85° C., 85 RH %, 60 days) | ◯ | ◯ | ◯ | ◯ | ◯ |
| | resistance test | | | | | | |

TABLE 5

| | | | | Comparative example | | | | | | |
|---|---|---|---|---|---|---|---|---|---|---|
| | Component | | Compound or the like | 1 | 2 | 3 | 4 | 5 | 6 | 7 |
| Composition | (A) | (A1) | Linear methylvinylpolysiloxane (A11) | 72.2 | 72.2 | 72.2 | 72.2 | 72.2 | 91.0 | 72.2 |
| (part by mass) | | | Linear methylvinylpolysiloxane (A12) | — | — | — | — | — | 9.0 | — |
| | | (A2) | Methylvinylpolysiloxane resin(A21) | 27.8 | 27.8 | 27.8 | 27.8 | 27.8 | — | 27.8 |
| | (B) | Linear methylhydrogenpolysiloxane (B1) | | 6.9 | 6.9 | 7.6 | 6.9 | 3.3 | 4.5 | 6.9 |
| | (C) | Platinum catalyst (in terms of platinum ppm | | 5 | 5 | 5 | 5 | 5 | 3 | 5 |
| | | relative to (A) + (B)) | | | | | | | | |
| | (D) | (D1) | 1:1 (mol) mixture of compound | — | — | — | — | 0.5 | 0.5 | 0.5 |
| | | | (D11-1) and compound (D11-2) | | | | | | | |
| | | | Compound (D11-3) | — | — | — | — | — | — | — |
| | | | 1:1 (mol) mixture of compound | — | — | — | — | — | — | — |
| | | | (D11-4) and compound (D11-5) | | | | | | | |
| | | | 1:1 (mol) mixture of compound | — | — | — | — | — | — | — |
| | | | (D11-6) and compound (D11-7) | | | | | | | |
| | | (D2) | Compound (D21-1) | 1.5 | 1.5 | — | — | 1.0 | 1.0 | 1.0 |
| | | | Compound (D23-1) | 0.5 | 0.5 | — | — | 0.5 | 0.5 | 0.5 |

| (D1)/(D2) mass ratio | | — | — | — | — | 0.33 | 0.33 | 0.33 |
|---|---|---|---|---|---|---|---|---|
| (E) | Cerium (III) 2-ethylhexanoate (in terms of Ce) | — | 0.02 | — | 0.003 | — | — | — |
| | Rare-earth element salt of 2-ethylhexanoic acid | — | — | — | — | — | — | — |
| | (in terms of rare-earth metal atoms) | | | | | | | |
| | Iron (III) 2-ethylhexanoate (in terms of Fe) | — | — | — | — | — | — | — |
| | Chromium (III) 2-ethylhexanoate (in terms of Cr) | — | — | — | — | — | — | — |
| (F) | Silica powder (F1) | — | — | — | — | — | 2.0 | 2.0 |
| (G) | Diallyl maleate | 0.03 | 0.03 | 0.03 | 0.03 | 0.03 | 0.02 | 0.03 |

| H bonded to Si of (B)/total Vi group of (A) (molar ratio) | | | 1.9 | 1.9 | 2.1 | 1.9 | 0.9 | 1.8 | 1.9 |
|---|---|---|---|---|---|---|---|---|---|
| H bonded to Si/Vi group in whole composition by (A), (B), | | | 2.1 | 2.1 | 2.1 | 1.9 | 0.9 | 1.8 | 1.9 |
| (D) components (molar ratio) | | | | | | | | | |
| Evaluation | Initial value | Hardness (Type A) (Hi) | 47 | 43 | 55 | 51 | 22 | 30 | 49 |
| | | Adhesiveness (PPA resin substrate) | ◯ | ◯ | X | X | ◯ | ◯ | ◯ |
| | | External appearance | ◯ | X | ◯ | ◯ | ◯ | ◯ | ◯ |
| | After | Hardness (Type A) (Hh) | 82 | 56 | 71 | 57 | 70 | 45 | 78 |
| | high-temperature | Difference in hardness (Hh − Hi) | 35 | 13 | 16 | 6 | 48 | 15 | 29 |
| | test (200° C., | Hardness change rate (%) | 74 | 30 | 29 | 12 | 218 | 50 | 59 |
| | 10 days) | ((Hh − Hi)/Hi × 100) | | | | | | | |
| | | Mass change rate (%) | −3.21 | −1.80 | −2.16 | −1.46 | −2.93 | −1.47 | −2.78 |
| | Silver (Ag) | (85° C., 85 RH %, 30 days) | X | ◯ | X | X | X | X | X |
| | corrosion | (85° C., 85 RH %, 60 days) | X | ◯ | X | X | X | X | X |
| | resistance test | | | | | | | | |

TABLE 6

| | | | | | | | | Comparative |
|---|---|---|---|---|---|---|---|---|
| | | | | Example | | | | example |
| | Component | | Compound or the like | 23 | 24 | 25 | 26 | 8 |
| Composition | (A) | (A2) | Methylphenylvinylpolysiloxane resin (A22) | 10.0 | 10.0 | 10.0 | 10.0 | 10.0 |
| (part by mass) | | | Methylphenylvinylpolysiloxane resin(A23) | 30.0 | 30.0 | 30.0 | 30.0 | 30.0 |
| | | | Methylphenylvinylpolysiloxane resin(A24) | 60.0 | 60.0 | 60.0 | 60.0 | 60.0 |
| | (B) | Methylphenylhydrogenpolysiloxane resin(B2) | | 8.2 | 8.2 | 8.2 | 8.2 | 8.2 |
| | | Linear methylphenylhydrogenpolysiloxane (B3) | | 8.0 | 8.0 | 8.0 | 8.0 | 8.0 |
| | (C) | Platinum catalyst (in terms of platinum ppm | | 5 | 5 | 5 | 5 | 5 |
| | | relative to (A) + (B)) | | | | | | |
| | (D) | (D1) | 1:1 (mol) mixture of compound (D11-1) | 1.0 | 1.0 | 1.0 | 1.0 | 1.0 |
| | | | and compound (D11-2) | | | | | |
| | | (D2) | Compound (D24-1) | 1.1 | 1.1 | 1.1 | 1.1 | 1.1 |

| (D1)/(D2) mass ratio | | 0.9 | 0.9 | 0.9 | 0.9 | 0.9 |
|---|---|---|---|---|---|---|
| (E) | Cerium (III) 2-ethylhexanoate (in terms of Ce) | 0.003 | — | — | — | — |
| | Rare-earth element salt of 2-ethylhexanoic acid | — | 0.005 | — | — | — |
| | (in terms of rare-earth metal atoms) | | | | | |
| | Iron (III) 2-ethylhexanoate (in terms of Fe) | — | — | 0.01 | — | — |
| | Chromium (III) 2-ethylhexanoate (in terms of Cr) | — | — | — | 0.003 | — |

| H bonded to Si of (B)/total Vi group of (A) (molar ratio) | | | 1.1 | 1.1 | 1.1 | 1.1 | 1.1 |
|---|---|---|---|---|---|---|---|
| H bonded to Si/Vi group in whole composition by (A), (B), (D) | | | 1.0 | 1.0 | 1.0 | 1.0 | 1.0 |
| components (molar ratio) | | | | | | | |
| Evaluation | Initial value | Hardness (Type A) (Hi) | 66 | 67 | 65 | 68 | 67 |
| | | Adhesiveness (PPA resin substrate) | ◯ | ◯ | ◯ | ◯ | ◯ |
| | | External appearance | ◯ | ◯ | ◯ | ◯ | ◯ |
| | After | Hardness (Type A) (Hh) | 80 | 81 | 80 | 79 | 81 |
| | high-temperature | Difference in hardness (Hh − Hi) | 14 | 14 | 15 | 11 | 14 |
| | test (200° C., | Hardness change rate (%) | 21 | 21 | 23 | 16 | 21 |
| | 10 days) | ((Hh − Hi)/Hi × 100) | | | | | |
| | | Mass change rate (%) | −3.07 | −3.24 | −3.07 | −3.04 | −3.08 |
| | Silver (Ag) | (85° C., 85 RH %, 30 days) | ◯ | ◯ | ◯ | ◯ | ◯ |
| | corrosion | (85° C., 85 RH %, 60 days) | ◯ | ◯ | ◯ | ◯ | X |
| | resistance test | (85° C., 85 RH %, 90 days) | ◯ | ◯ | ◯ | ◯ | X |

[Measurement of Adhesiveness to Silver (Ag)]

End portions at one end of two substrates (having a thickness of 1 mm) made of Ag having a width of 25 mm were overlapped over a length of 10 mm while holding a layer having a thickness of 1 mm composed of each of the compositions prepared in Examples 1 to 5, 10, 23 to 26 and Comparative examples 1 to 4, 8, therebetween, and the composition layer was heated at 150° C. for 2 hours and thereby cured. A test object thus fabricated was let stand at room temperature for 12 hours or more, and then subjected to measurement of the tensile cohesive failure rate by pulling both ends of the test object by a tensile tester according to JIS K6256-2. Then, the adhesiveness was evaluated based on the following criteria.

The results are listed in Table 7.

◯: Cohesive failure rate exceeds 60%.

Δ: Cohesive failure rate is within a range of 10 to 60%.

X: Cohesive failure rate is less than 10%.

TABLE 7

| | | Adhesiveness (silver |
|---|---|---|
| | | (Ag) substrate) |
| Example | 1 | ◯ |
| | 2 | ◯ |
| | 3 | ◯ |
| | 4 | ◯ |
| | 5 | ◯ |
| | 10 | Δ |
| | 23 | ◯ |
| | 24 | ◯ |
| | 25 | ◯ |
| | 26 | ◯ |
| Comparative | 1 | X |
| example | 2 | X |
| | 3 | X |
| | 4 | X |
| | 8 | ◯ |

As is found from Tables 1 to 4, 6, the silicone cured products obtained by curing the addition-curable silicone compositions obtained in the examples have excellent adhesiveness and external appearance, and less shrinkage and change in hardness due to heat. The silicone cured products further have an action to protect silver. In contrast to this, the silicone cured products obtained by curing the addition-curable silicone compositions obtained in the comparative examples listed in Tables 5, 6 are insufficient at least in one of adhesiveness, external appearance, hardness change, heat shrinkage, and function to protect silver. It is found from Table 7 that the addition-curable silicone compositions in the above-described examples are also excellent in adhesiveness to the Ag substrate.

What is claimed is:

1. An addition-curable silicone composition, comprising:
(A) 100 parts by mass of a polyorganosiloxane having at least one alkenyl group bonded to a silicon atom in one molecule, and having neither an epoxy group nor an alkoxy group;
(B) an amount of a polyorganohydrogensiloxane having at least two hydrogen atoms bonded to silicon atoms in one molecule such that an amount of the hydrogen atoms bonded to silicon atoms is 0.9 to 3.0 mol relative to 1 mol of a total amount of the alkenyl groups contained in the (A) component;
(C) a catalyst amount of a hydrosilylation reaction catalyst;
(D) as an adhesiveness imparting agent, 0.01 to 10 parts by mass of at least one selected from (D1) an isocyanuric acid derivative having at least one selected from an epoxy group and an alkoxysilyl group and at least one selected from a hydrosilyl group and a crosslinking vinyl group and (D2) a silane or siloxane compound having at least one selected from an epoxy group and an alkoxy group, and having no isocyanuric ring; and
(E) 0.001 to 0.015 parts by mass, in terms of metal atoms, of a carboxylic acid metal salt represented by a following general formula (3),
(R³COO)ₖM (3)
where M represents a metal atom selected among Ce, Fe, Cr, La, Nd, Pr and Sm, k represents a positive number from 2 to 4, and R³ represents a substituted or unsubstituted hydrocarbon group having 4 to 17 carbon atoms.

2. The addition-curable silicone composition according to claim 1,
wherein the (A) component is composed of a polyorganosiloxane (A1) represented by a following general formula (1), and a polyorganosiloxane (A2) represented by a following average unit formula (2),
(R¹₃SiO_{1/2})(R¹₂SiO)ₙ(R¹₃SiO_{1/2}) (1)
where each R¹ independently represents an alkenyl group or a monovalent unsubstituted or substituted hydrocarbon group containing none of an aliphatic unsaturated group, an epoxy group, and an alkoxy group, at least two R¹s are alkenyl groups, and an average degree of polymerization expressed by n+2 is 50 to 2,500; and
(R²₃SiO_{1/2})ₙ(R²₂SiO_{2/2})_{b}(R²SiO_{3/2})_{c}(SiO_{4/2})_{d} (2)
where each R² independently represents an alkenyl group or a monovalent unsubstituted or substituted hydrocarbon group containing none of an aliphatic unsaturated group, an epoxy group, and an alkoxy group, at least one R² is an alkenyl group, and a is a positive number, b, c, and d are 0 or positive numbers, and at least one of c and d is a positive number.

3. The addition-curable silicone composition according to claim 2,
wherein a relationship among a, b, c, d in the average unit formula (2) satisfies 0<a/(c+d)<3 and 0≦b/(c+d)<2.

4. The addition-curable silicone composition according to claim 2,
wherein a ratio of the polyorganosiloxane (A2) relative to 100 parts by mass of a total amount of the polyorganosiloxane (A1) and the polyorganosiloxane (A2) is 5 to 100 parts by mass.

5. The addition-curable silicone composition according to claim 1,
wherein the (A) component mainly comprises the polyorganosiloxane (A1) represented by the following general formula (1), and further comprises 0.1 to 10 parts by mass of (F) silica powder,
(R¹₃SiO_{1/2})(R¹₂SiO)(R¹₃SiO_{1/2}) (1)
where each R¹ independently represents an alkenyl group or a monovalent unsubstituted or substituted hydrocarbon group containing none of an aliphatic unsaturated group, an epoxy group, and an alkoxy group, at least two R¹s are alkenyl groups, and an average degree of polymerization expressed by n+2 is 50 to 2,500.

6. The addition-curable silicone composition according to claim 1,
wherein, the (B) polyorganohydrogensiloxane is represented by a following general formula (4)
R⁴ₚH_{q}SiO_{(4-p-q)/2} (4)
where R⁴ represents an unsubstituted or substituted monovalent hydrocarbon group having no aliphatic unsaturated group, and p and q are positive numbers satisfying 0.7≦p≦2.1, 0.001≦q≦1.0 and (p+q)≦3.0.

7. The addition-curable silicone composition according to claim 1, comprising, as the (D) adhesiveness imparting agent, at least one of the (D1) isocyanuric acid derivative and at least one of the (D2) silane or siloxane compound, at a mass ratio represented by (D1)/(D2) of 0.1 to 3.0.

8. The addition-curable silicone composition according to claim 1, further comprising (G) 0.001 to 0.1 parts by mass of an addition reaction inhibitor.

9. The addition-curable silicone composition according to claim 1, for sealing or die-attaching an optical semiconductor element.
